(19) United States
(12) Patent Application Publication
(10) Pub. No.: US 2020/0294554 A1
(43) Pub. Date: Sep. 17, 2020

(54) SEMICONDUCTOR MEMORY DEVICE

(71) Applicant: Toshiba Memory Corporation, Minato-ku (JP)

(72) Inventors: Takayuki KAKEGAWA, Yokkaichi (JP); Shinya NAITO, Toyota (JP); Masaki KONDO, Yokkaichi (JP); Takashi KURUSU, Yokkaichi (JP); Hiroshi TAKEDA, Yokkaichi (JP); Nayuta KARIYA, Yokkaichi (JP)

(73) Assignee: Toshiba Memory Corporation, Minato-ku (JP)

(21) Appl. No.: 16/557,475

(22) Filed: Aug. 30, 2019

(30) Foreign Application Priority Data
Mar. 15, 2019 (JP) 2019-049081

(51) Int. Cl. G11C 5/06; H01L 27/11556; H01L 27/11524

(52) U.S. Cl. CPC G11C 5/063; H01L 27/11524; H01L 27/11556

(57) ABSTRACT

A semiconductor memory device according to an embodiment includes a substrate, first and second conductive layers, and a first pillar. The first conductive layer is provided above the substrate and includes a first N-type semiconductor region and a first P-type semiconductor region. The second conductive layers are provided above the first conductive layer and stacked at intervals. The first pillar includes a first semiconductor layer and a first insulating layer. The first semiconductor layer is provided through the second conductive layers and is in contact with each of the first N-type semiconductor region and the first P-type semiconductor region. The first insulating layer is provided between the first semiconductor layer and the second conductive layers.

### CROSS-REFERENCE TO RELATED APPLICATION

This application is based upon and claims the benefit of priority from Japanese Patent Application No. 2019-049081, filed Mar. 15, 2019, the entire contents of which are incorporated herein by reference.

### FIELD

Embodiments described herein relate generally to a semiconductor memory device.

### BACKGROUND

A NAND-type flash memory that is capable of storing data in a nonvolatile manner is known.

### BRIEF DESCRIPTION OF THE DRAWINGS

FIG. 1 is a block diagram showing an example of a configuration of a semiconductor memory device according to a first embodiment.

FIG. 2 is a circuit diagram showing an example of a circuit configuration of a memory cell array of the semiconductor memory device according to the first embodiment.

FIG. 3 is a plan view showing an example of a planar layout of the memory cell array of the semiconductor memory device according to the first embodiment.

FIG. 4 is a plan view showing an example of a planar layout of a memory cell array of a semiconductor memory device according to a modification to the first embodiment.

FIG. 5 is a plan view showing an example of a detailed planar layout of the memory cell array of the semiconductor memory device according to the first embodiment.

FIG. 6 is a sectional view taken along line VI-VI of FIG. 5 and showing an example of a sectional structure of the memory cell array of the semiconductor memory device according to the first embodiment.

FIG. 7 is a sectional view taken along line VII-VII of FIG. 6 and showing an example of a sectional structure of a memory pillar in the semiconductor memory device according to the first embodiment.

FIG. 8 is a schematic diagram showing an example of electron behavior in the read operation of the semiconductor memory device according to the first embodiment.

FIG. 9 is a schematic diagram showing an example of hole behavior in the erase operation of the semiconductor memory device according to the first embodiment.

FIG. 10 is a circuit diagram showing an example of a circuit configuration of a memory cell array of a semiconductor memory device according to a second embodiment.

FIG. 11 is a sectional view showing an example of a sectional structure of a memory pillar of the semiconductor memory device according to the second embodiment.

FIG. 12 is a sectional view taken along line XII-XII of FIG. 11 and showing an example of a sectional structure of the memory pillar of the semiconductor memory device according to the second embodiment.

FIGS. 13 through 23 are sectional views each showing an example of a sectional structure of the semiconductor memory device according to the second embodiment which is in the process of manufacture.

FIG. 24 is a schematic diagram showing an example of electron and hole behavior in the read operation of the semiconductor memory device according to the second embodiment.

FIG. 25 is a schematic diagram showing an example of hole behavior in the erase operation of the semiconductor memory device according to the second embodiment.

FIG. 26 is a schematic diagram showing another example of electron and hole behavior in the read operation of the semiconductor memory device according to the second embodiment.

FIG. 27 is a sectional view showing an example of a sectional structure of a memory pillar of a semiconductor memory device according to a first modification to the second embodiment.

FIG. 28 is a sectional view taken along line XXVIII-XXVIII of FIG. 27 and showing an example of a sectional structure of the memory pillar of the semiconductor memory device according to the first modification to the second embodiment.

FIG. 29 is a sectional view showing an example of a sectional structure of a memory pillar of a semiconductor memory device according to a second modification to the second embodiment.

FIG. 30 is a sectional view showing an example of a sectional structure of a memory pillar of a semiconductor memory device according to a third modification to the second embodiment.

### DETAILED DESCRIPTION

In general, according to one embodiment, a semiconductor memory device includes a substrate, a first conductive layer, a plurality of second conductive layers, and a first pillar. The first conductive layer is provided above the substrate. The first conductive layer includes a first N-type semiconductor region and a first P-type semiconductor region arranged in a direction parallel to a surface of the substrate. The second conductive layers are provided above the first conductive layer. The second conductive layers are stacked at intervals in a first direction. The first pillar is provided through the second conductive layers along the first direction. The first pillar includes a first semiconductor layer and a first insulating layer. The first semiconductor layer is in contact with the first N-type semiconductor region and the first P-type semiconductor region. The first insulating layer is provided between the first semiconductor layer and the second conductive layers.

The embodiment will be described below with reference to the accompanying drawings. The embodiment is directed to an example of a device and a method for embodying the technical concept of the invention. The drawings are schematic or conceptual, and none of the dimensions, ratio, etc. in each of the drawings is necessarily the same as the actual one. The technical concept of the invention is not limited by the shape, configuration, placement, etc. of the structural elements.

In the following descriptions, the structural elements having substantially the same function and configuration are denoted by the same numeral or sign. The number subsequent to a letter or letters in a reference sign is used to distinguish structural elements referred to by reference signs including the same letter or letters and having the same configuration. If the structural elements denoted by the reference signs including the same letter or letters need not be distinguished from each other, they include only the same letter or letters and not a number subsequent thereto.

### [1] First Embodiment

Hereinafter, a semiconductor memory device 1 according to a first embodiment will be explained.

### [1-1] Configuration of Semiconductor Memory Device 1

[1-1-1] Overall Configuration of Semiconductor Memory Device 1

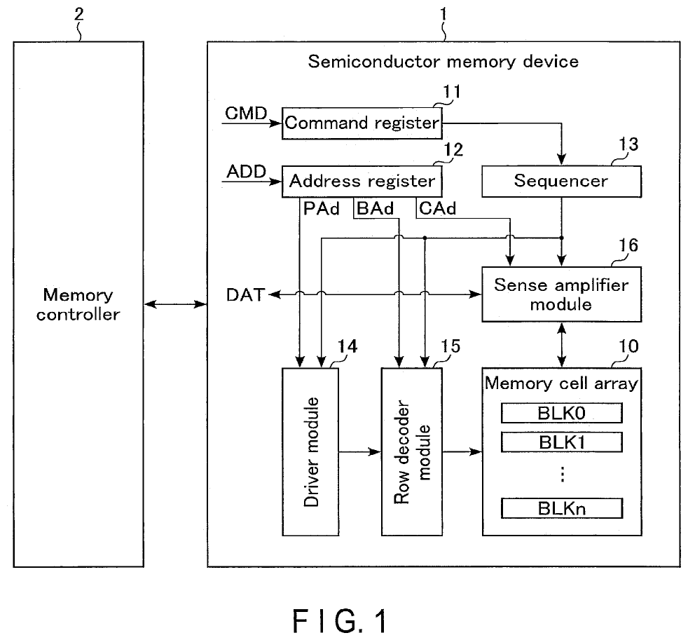

FIG. 1 shows an example of a configuration of the semiconductor memory device 1 according to the first embodiment. The semiconductor memory device 1 is a NAND flash memory capable of storing data in a nonvolatile manner and is controlled by an external memory controller 2. Communications between the semiconductor memory 1 and the memory controller 2 supports, for example, the NAND interface standard.

As shown in FIG. 1, the semiconductor memory 1 includes, for example, a memory cell array 10, a command register 11, an address register 12, a sequencer 13, a driver module 14, a row decoder module 15 and a sense amplifier module 16.

The memory cell array 10 includes a plurality of blocks BLK0 to BLKn (n is an integer of one or more). The block BLK is a set of memory cells capable of storing data in a nonvolatile manner and is used as, for example, a unit of data erase. The memory cell array 10 also includes a plurality of bit lines and a plurality of word lines. Each of the memory cells is associated with, for example, one bit line and one word line. The configuration of the memory cell array 10 will be described in detail later.

The command register 11 holds a command CMD which the semiconductor memory device 1 has received from the memory controller 2. The command CMD includes, for example, instructions to cause the sequencer 13 to perform a read operation, a write operation, an erase operation and the like.

The address register 12 holds address information ADD which the semiconductor memory device 1 has received from the memory controller 2. The address information ADD includes, for example, a block address BAd, a page address Pad and a column address CAd. For example, the block address BAd, page address PAd and column address CAd are used to select a block BLK, a word line and a bit line, respectively.

The sequencer 13 controls the entire operation of the semiconductor memory device 1. For example, the sequencer 13 controls the driver module 14, row decoder module 15, sense amplifier module 16 and the like based on the command CMD held in the command register 11 to perform a read operation, a write operation, an erase operation and the like.

The driver module 14 generates a voltage to be used in the read operation, write operation, erase operation and the like. Then, the driver module 14 applies the generated voltage to a signal line corresponding to a selected word line based on, for example, the page address PAd held in the address register 12.

The row decoder module 15 selects one block BLK in the memory cell array 10, based on the block address BAd held in the address register 12. Then, the row decoder module 15 transfers, for example, the voltage applied to the signal line corresponding to the selected word line, to a selected word line in the selected block BLK.

In the write operation, the sense amplifier module 16 apples a desired voltage to each bit line in accordance with write data DAT received from the memory controller 2. In the read operation, the sense amplifier module 16 determines data stored in a memory cell based on the voltage of the bit line and transfers a result of the determination to the memory controller 2 as read data DAT.

The semiconductor memory device 1 and the memory controller 2 described above may be combined into one semiconductor device. This semiconductor device includes a memory card such as an SDTM card, a solid-state drive (SSD), and the like.

[1-1-2] Circuit Configuration of Memory Cell Array 10

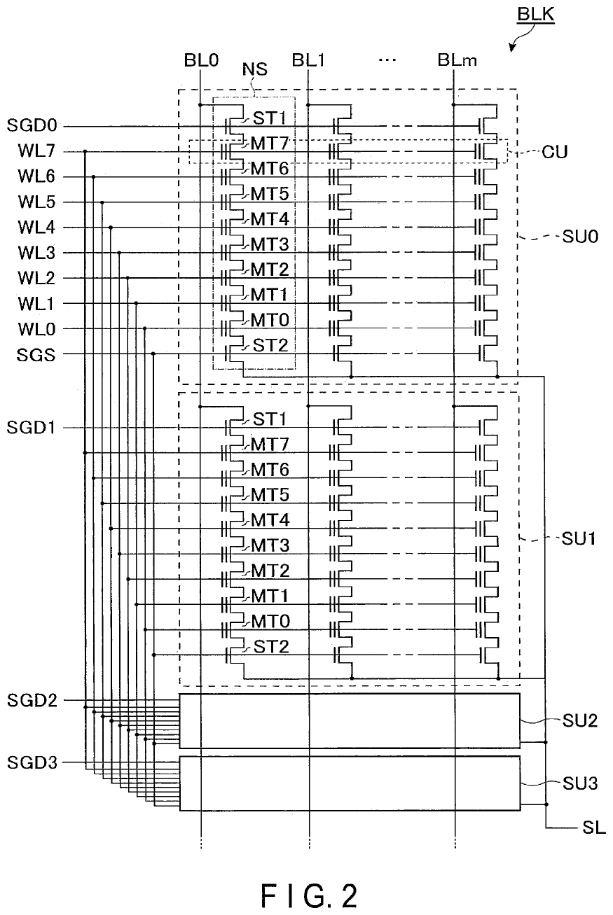

FIG. 2 shows an example of a circuit configuration of the memory cell array 10 of the semiconductor memory device 1 according to the first embodiment, extracting one of the blocks BLK included in the memory cell array 10. As shown in FIG. 2, the block BLK includes, for example, four string units SU0 to SU3.

Each string unit SU includes a plurality of NAND strings NS associated with their respective bit lines BL0 to BLm (m is an integer of one or more). Each NAND string NS includes, for example, memory cell transistors MT0 to MT7 and select transistors ST1 and ST2. The memory cell transistor MT includes a control gate and a charge storage layer to hold data in a nonvolatile manner. Each of the select transistors ST1 and ST2 is used to select a string unit SU in each of the operations.

In each NAND string NS, the memory cell transistors MT0 to MT7 are connected in series. The drain of the select transistor ST1 is connected to its associated bit line BL and the source thereof is connected to one end of the series-connected memory cell transistors MT0 to MT7. The drain of the select transistor ST2 is connected to the other end of the series-connected memory cell transistors MT0 to MT7. The source of the select transistor ST2 is connected to a source line SL.

In the same block BLK, the control gates of the memory cell transistors MT0 to MT7 are connected to their respective word lines WL0 to WL7. The gates of the select transistors ST1 in the string units SU0 to SU3 are connected to their respective select gate lines SGD0 to SGD3. The gates of the select transistors ST2 are connected in common to the select gate line SGS.

In the circuit configuration of the memory cell array 10 described above, each bit line BL is shared by a NAND string NS to which the same column address is assigned in each string unit SU. The source line SL is shared by, for example, the blocks BLK.

A set of memory cell transistors MT connected to a common word line WL in one string unit SU is referred to as, for example, a cell unit CU. For example, the storage capacity of the cell unit CU including memory cell transistors MT each storing one-bit data is defined as “one-page data.” The cell unit CU may have a storage capacity of data of two or more pages according to the number of bits of data to be stored in the memory cell transistor MT.

Note that the circuit configuration of the memory cell array 10 of the semiconductor memory device 1 according to the first embodiment is not limited to the configuration described above. For example, the number of memory cell transistors MT and the number of select transistors ST1 and ST2, which are included in each NAND string NS, can optionally be set. The number of string units SU included in each block BLK can optionally be set.

[1-1-3] Configuration of Memory Cell Array 10

An example of the configuration of the memory cell array 10 in the first embodiment will be described below.

In the figures referred to below, the X direction corresponds to the extending direction of the word line WL, the Y direction corresponds to the extending direction of the bit line BL, and the Z direction corresponds to a direction perpendicular to the surface of a semiconductor substrate 20 on which the semiconductor memory device 1 is formed. Hatching is added to the plan views as appropriate for clarification. The hatching attached to the plan views is not necessarily related to the materials or properties of the structural elements to which the hatching is added. In the present specification, structural elements such as an insulator layer (interlayer insulating film), interconnect and contacts will be omitted as appropriate for clarification.

(Planar Layout of Memory Cell Array 10)

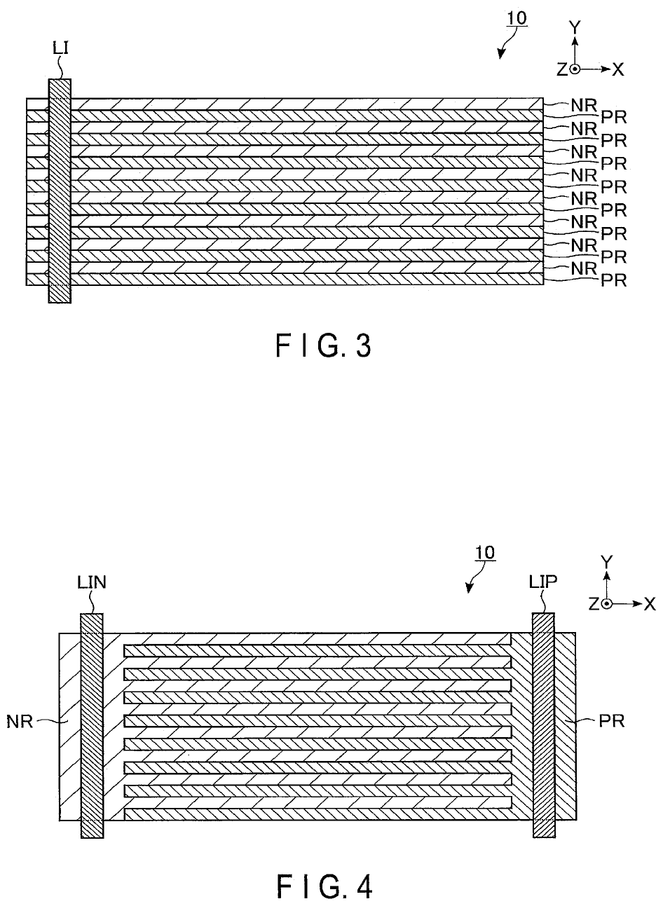

FIG. 3 shows an example of a planar layout of the memory cell array 10 of the semiconductor memory device 1 according to the first embodiment, extracting part of the memory cell array 10. As shown in FIG. 3, the memory cell array 10 includes, for example, a plurality of N-type semiconductor regions NR, a plurality of P-type semiconductor regions PR and a contact LI.

The N-type semiconductor regions NR are semiconductor regions into which N-type impurities are diffused. The N-type semiconductor regions NR are doped with, for example, phosphorus (P) or arsenic (As). The P-type semiconductor regions PR are semiconductor regions into which P-type impurities are diffused. The P-type semiconductor regions PR are doped with, for example, boron (B). For example, the N-type semiconductor regions NR and P-type semiconductor regions PR are provided to extend in the X direction and arranged alternately in the Y direction. In other words, the N-type semiconductor regions NR and P-type semiconductor regions PR are arranged in stripes.

The contact LI is electrically connected to the N-type semiconductor regions NR and P-type semiconductor regions PR. The contact LI is formed, for example, like a plate extending in the Y direction and placed in an area at one end of the alternately-arranged N-type semiconductor regions NR and P-type semiconductor regions PR in the X direction. Two or more contacts LI may be connected to the N-type semiconductor regions NR and P-type semiconductor regions PR.

FIG. 4 shows an example of a planar layout of the memory cell array 10 of the semiconductor memory device 1 according to a modification to the first embodiment, extracting part of the memory cell array 10. As shown in FIG. 4, the memory cell array 10 may include a comb-shaped N-type semiconductor region NR, a comb-shaped P-type semiconductor region PR and contacts LIN and LIP.

In the modification to the first embodiment, specifically, the comb-shaped portions of the N-type semiconductor region NR and P-type semiconductor region PR are arranged in stripes as in FIG. 3. The comb-shaped portions of the N-type semiconductor region NR are provided continuously with a connection area extending in the Y direction at one end in the X direction, and the comb-shaped portions of the P-type semiconductor region PR are provided continuously with a connection area extending in the Y direction at the other end in the X direction.

The contact LIN is placed to overlap the connection area of the N-type semiconductor region NR and electrically connected to the N-type semiconductor region NR. The contact LIP is placed to overlap the connection area of the P-type semiconductor region PR and electrically connected to the P-type semiconductor region PR. The contacts LIN and LIP may be controlled in common or independently. That is, in the modification to the first embodiment, the driver module 14 can apply different voltages to the N-type semiconductor region NR and P-type semiconductor region PR.

Note that in the first embodiment and its modification, the contact LI, LIN or LIP need not be shaped like a plate. Each of the contacts LI, LIN and LIP may be formed by a plurality of columnar contacts.

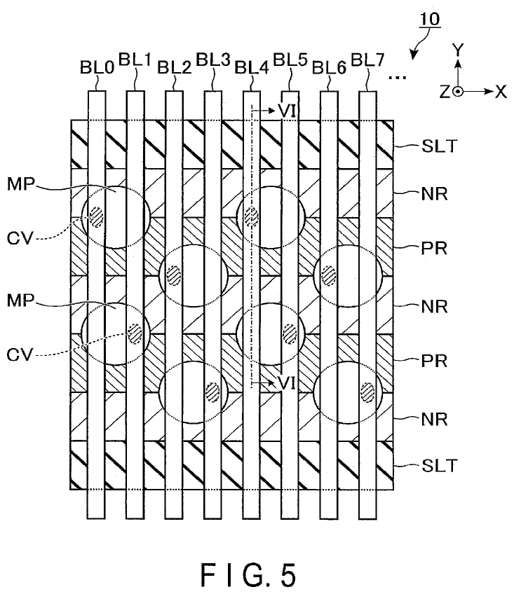

FIG. 5 shows an example of a detailed planar layout of the memory cell array 10 of the semiconductor memory device 1 according to the first embodiment, extracting an area corresponding to one string unit SU. As shown in FIG. 5, the memory cell array 10 further includes, for example, a plurality of slits SLT, a plurality of memory pillars MP, a plurality of contacts CV and a plurality of bit lines BL.

The slits SLT extend in the X direction and are arranged in the Y direction. Each slit SLT includes an insulator and isolates, for example, an interconnect layer corresponding to the word line WL, an interconnect layer corresponding to the select gate line SGD and an interconnect layer corresponding to the select gate line SGS.

Each of the memory pillars MP functions as, for example, one NAND string NS. The memory pillars MP are arranged in four columns in a staggered manner. Each of the memory pillars MP is placed to overlap the N-type and P-type semiconductor regions NR and PR which are adjacent in the Y direction.

In this example, two memory pillars MP which are adjacent in the Y direction overlap different N-type and P-type semiconductor regions NR and PR. Adjacent two memory pillars which are displaced in the X and Y directions share only one of the N-type and P-type semiconductor regions NR and PR. Note that each of the memory pillars MP has only to overlap both of at least adjacent N-type and P-type semiconductor regions NR and PR.

The bit lines BL extend in the Y direction and are arranged in the X direction. Each of the bit lines BL is placed to overlap at least one memory pillar MP for each string unit SU. In this example, two bit lines BL are placed on each memory pillar MP. A contact CV is provided between the memory pillar MP and one of the bit lines BL placed on the memory pillar MP. Each memory pillar MP is electrically connected to its corresponding bit line BL via the contact CV.

In the planar layout of the memory cell array 10 of the semiconductor memory device 1 according to the first embodiment described above, a region separated by a slit SLT corresponds to one string unit SU. In the memory cell array 10, for example, the layout shown in FIG. 5 is repeated in the Y direction.

Note that the number or the arrangement of memory pillars between adjacent slits SLT is not limited to the configuration described with reference to FIG. 5 but can be changed as appropriate. A slit by which the select gate line SGD is isolated may be provided between adjacent slits SLT. When the select gate line SGD is isolated by the slit provided between adjacent slits SLT, a plurality of string units SU are provided between the adjacent slits SLT.

(Sectional Structure of Memory Cell Array 10)

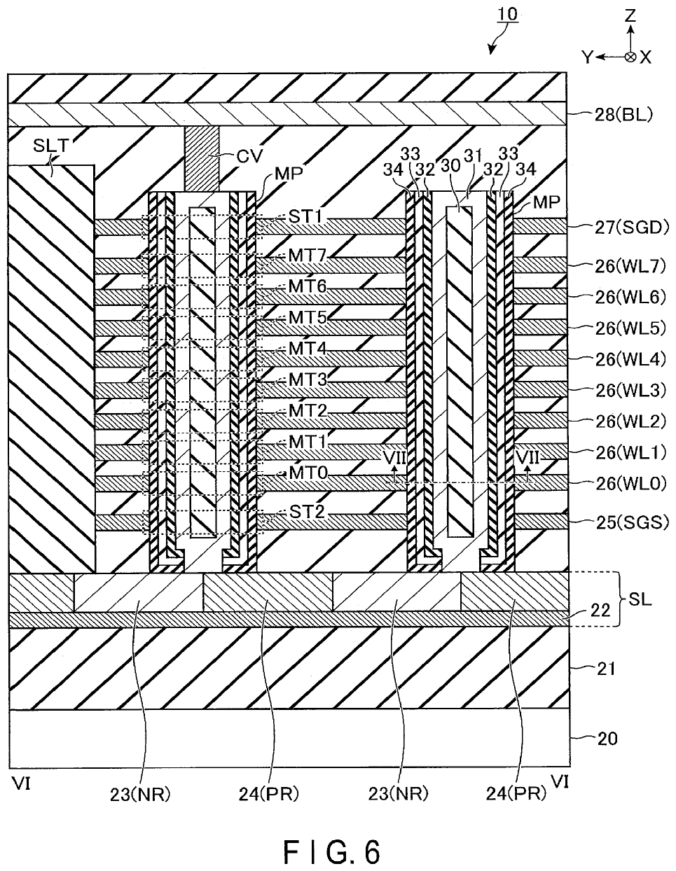

FIG. 6 is a sectional view taken along line VI-VI of FIG. 5 and showing an example of a sectional structure of the memory cell array 10 of the semiconductor memory device 1 according to the first embodiment. As shown in FIG. 6, the memory cell array 10 further includes, for example, an insulator layer 21, a conductive layer 22, a plurality of N-type semiconductor layers 23, a plurality of P-type semiconductor layers 24 and conductive layers 25 to 28.

Specifically, the insulator layer 21 is provided on the semiconductor substrate 20. Though not shown, a circuit such as the sense amplifier module 16 is provided inside the insulator layer 21. The conductive layer 22 is provided on the insulator layer 21. The conductive layer 22 is formed like a plate expanding along, for example, the XY plane and contains, for example, tungsten (W). Note that the conductive layer 22 may be formed of a semiconductor or may be excluded.

A plurality of N-type semiconductor layers 23 and a plurality of P-type semiconductor layers 24 are provided on the conductive layer 22. In other words, a semiconductor layer is provided on the conductive layer 22 and includes a plurality of N-type semiconductor layers 23 doped with N-type impurities and a plurality of P-type semiconductor layers 24 doped with P-type impurities. The N-type semiconductor layers 23 contain, for example, phosphorus (P) or arsenic (As). The P-type semiconductor layers 24 contain, for example, boron (B).

The N-type semiconductor layers 23 correspond to N-type semiconductor regions NR and the P-type semiconductor layers 24 correspond to P-type semiconductor regions PR. That is, the N-type semiconductor layers 23 and the P-type semiconductor layers 24 are provided alternately in the Y direction. Further, the N-type semiconductor layers 23 and the P-type semiconductor layers 24 are aligned with each other. In the first embodiment, a set of the conductive layer 22, the N-type semiconductor layers 23 and the P-type semiconductor layers 24 is used as a source line SL.

The conductive layer 25 is provided above the N-type semiconductor layers 23 and the P-type semiconductor layers 24 with an insulator layer therebetween. The conductive layer 25 is formed like a plate expanding along, for example, the XY plane and used as a select gate line SGS. The conductive layer 25 contains, for example, tungsten (W).

The insulator layers and the conductive layers 26 are stacked alternately above the conductive layer 25. The conductive layers 26 are each formed like a plate expanding along, for example, the XY plane. For example, the stacked conductive layers 26 are used as their respective word lines WL0 to WL7 in order from the semiconductor substrate 20 side. The conductive layers 26 contain, for example, tungsten (W).

The conductive layer 27 is provided above the uppermost conductive layer 26 with an insulator layer therebetween. The conductive layer 27 is formed like a plate expanding along, for example, the XY plane and used as a select gate line SGD. The conductive layer 27 contains, for example, tungsten (W).

The conductive layer 28 is provided above the conductive layer 27 with an insulator layer therebetween. For example, the conductive layer 28 is formed linearly to extend along the Y direction and used as a bit line BL. That is, a plurality of conductive layers 28 are arranged along the X direction in a region not shown. The conductive layers 28 contain, for example, copper (Cu).

The memory pillars MP are provided to extend along the Z direction and penetrate the conductive layers 25 to 27. Each of the memory pillars MP includes, for example, a core member 30, a semiconductor layer 31, a tunnel insulating film 32, an insulating film 33 and a block insulating film 34.

The core member 30 is provided to extend along the Z direction. For example, the upper end of the core member 30 is included in a layer that is higher than the conductive layer 27, and the lower end of the core member 30 is included in a layer that is lower than the conductive layer 25. The semiconductor layer 31 covers, for example, the periphery of the core member 30. The bottom of the semiconductor layer 31 is in contact with each of adjacent N-type and P-type semiconductor layers 23 and 24. The tunnel insulating film 32 covers the side of the semiconductor layer 31. The insulating film 33 covers the side of the tunnel insulating film 32. The block insulating film 34 covers the side of the insulating film 33.

The core member 30 includes an insulator such as silicon oxide (SiO₂). The semiconductor layer 31 contains, for example, silicon. Each of the tunnel insulating film 32 and the block insulating film 34 contains, for example, silicon oxide (SiO₂). The insulating film 33 contains, for example, silicon nitride (SiN).

A columnar contact CV is connected to the top surface of the semiconductor layer 31 in the memory pillar MP. In the region shown in FIG. 6A, a contact CV is connected to one of the two memory pillars MP. In a region not shown, a contact CV is connected to the other memory pillar MP.

One conductive layer 28, i.e. one bit line BL is in contact with the top surface of the contact CV. One contact CV is connected one conductive layer 28 in each space interposed between adjacent slits SLT.

The slit SLT is formed like a plate expanding along, for example, the XZ plane and isolates the conductive layers 25 to 27. The upper end of the slit SLT is included in a layer between the conductive layers 27 and 28, and the lower end of the slit SLT is included in a layer that is lower than the conductive layer 25. The slit SLT contains an insulator such as silicon oxide (SiO₂).

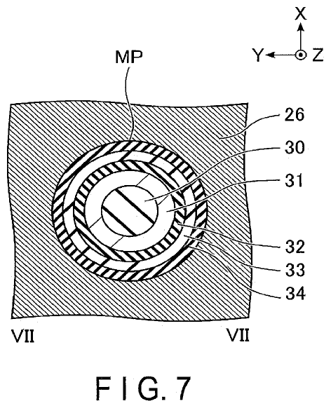

FIG. 7 is a sectional view taken along line VII-VII of FIG. 6 and showing an example of a sectional structure of the memory pillar MP in the semiconductor memory device 1 according to the first embodiment. More specifically, FIG. 7 shows a sectional structure of the memory pillar MP in a layer which is parallel to the surface of the semiconductor substrate 20 and which includes the conductive layer 26. As shown in FIG. 7, in the layer including the conductive layer 26, for example, the core member 30 is provided in the central part of the memory pillar MP. The semiconductor layer 31 surrounds the side of the core member 30. The tunnel insulating film 32 surrounds the side of the semiconductor layer 31. The insulating film 33 surrounds the side of the tunnel insulating film 32. The block insulating film 34 surrounds the side of the insulating film 33. The conductive layer 26 surrounds the side of the block insulating film 34.

In the configuration of the memory pillar MP described above, a portion where the memory pillar MP and the conductive layer 25 intersect functions as a select transistor ST2. A portion where the memory pillar MP and the conductive layer 26 intersect functions as a memory cell transistor MT. A portion where the memory pillar MP and the conductive layer 27 intersect functions as a select transistor ST1. That is, the semiconductor layer 31 is used as a channel of each of the memory cell transistor MT and the select transistors ST1 and ST2. The insulating film 33 is used as a charge storage layer of the memory cell transistor MT. Thus, each of the memory pillars MP functions as, for example, one NAND string NS.

Note that the configuration of the memory cell array 10 described above is only one example and thus the memory cell array 10 may have other configurations. For example, the number of conductive layers 26 is designed based upon the number of word lines WL. A plurality of conductive layers 25 formed in a plurality of layers may be assigned to the select gate line SGS. When the select gate line SGS is formed in a plurality of layers, a conductor other than the conductive layer 25 may be used. A plurality of conductive layers 27 formed in a plurality of layers may be assigned to the select gate line SGD. The memory pillar MP and the conductive layer 28 may be electrically connected via two or more contacts or via other interconnects. The slit SLT may be filled with a plurality of types of insulator. For example, before the slit SLT is filled with silicon oxide, silicon nitride (SiN) may be formed as the side wall of the slit SLT.

### [1-2] Operations of Semiconductor Memory Device 1

The read operation and erase operation of the semiconductor memory device 1 according to the first embodiment will be described below. In order to describe the operations, a portion corresponding to one memory pillar MP shown in FIG. 6 is extracted, and the drawings are used to illustrate one example of a voltage applied to each of the source line SL, bit line BL, word line WL, and select gate lines SGD and SGS at a certain time and the behavior of electrons or holes passing through the memory pillar MP.

In each of the read and erase operations described below, it is assumed that the voltage of the bit line BL is controlled by the sense amplifier module 16, the voltage of each of the word line WL and the select gate lines SGD and SGS is controlled by the row decoder module 15, and the voltage of the source line SL is controlled by the driver module 14. In the read operation, the selected word line WL will be referred to as a select word line and the non-selected word line WL will be referred to as a non-select word line. The memory cell transistor MT connected to the select word line will be referred to as a select memory cell. The voltage applied to each interconnect will be denoted only as an appropriate reference symbol.

(Read Operation)

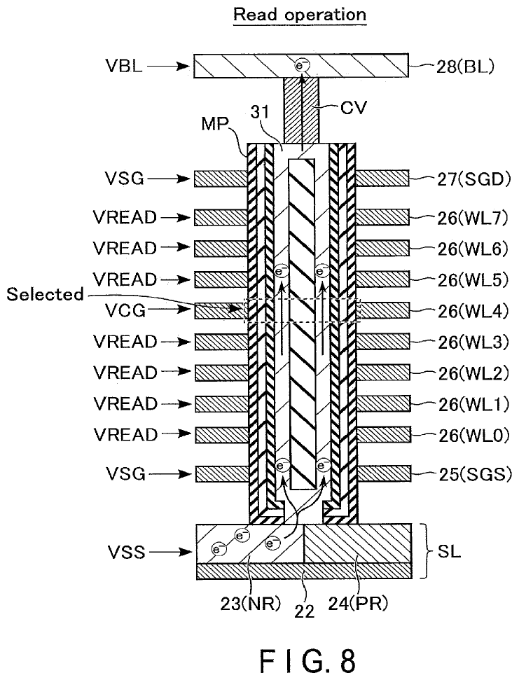

FIG. 8 shows an example of electron behavior in the read operation of the semiconductor memory device 1 according to the first embodiment. As shown in FIG. 8, in the read operation, for example, a voltage VBL is applied to the bit line BL, a voltage VSS is applied to the source line SL, a voltage VSG is applied to each of the select gate lines SGD and SGS, a read voltage VCG is applied to the select word line WL, and a read pass voltage VREAD is applied to the non-select word line WL.

VSS is a ground voltage and, for example, 0 V. VBL is higher than VSS. VSG is higher than VSS and, in the read operation, it turns on the select transistors ST1 and ST2 to which VSG is applied. VCG is a voltage to check the threshold voltage of the memory cell transistor MT. VREAD is higher than VCG and turns on the memory cell transistor MT to which VREAD is applied, regardless of data stored therein.

In the read operation, when the foregoing voltages are applied, the select transistor ST1 connected to the select gate line SGD, the select transistor ST2 connected to the select gate line SGS, and the memory cell transistor MT connected to the non-select word line WL are turned on. The select memory cell connected to the select word line WL is turned on or off based on data to be stored therein. FIG. 8 shows an example of a case where the select memory cell is turned on.

During the on state of the select memory cell, current flows through the channel of the NAND string NS (semiconductor layer 31 in the memory pillar MP) between the source line SL and the bit line BL. Specifically, electrons (e⁻) contained in the N-type semiconductor region NR of the source line SL move toward the bit line BL whose voltage is higher than that of the source line SL through the semiconductor layer 31. That is, in the read operation of the semiconductor memory device 1 according to the first embodiment, the electrons flowing through the NAND string NS are supplied from the N-type semiconductor region NR (N-type semiconductor layer 23).

When the voltage of the bit line BL varies with the state of the select memory cell, the sense amplifier module 16 determines the threshold voltage of the memory cell transistor MT based on the voltage of the bit line BL. As described above, the semiconductor memory device 1 according to the first embodiment can read data out of the select memory cell.

(Erase Operation)

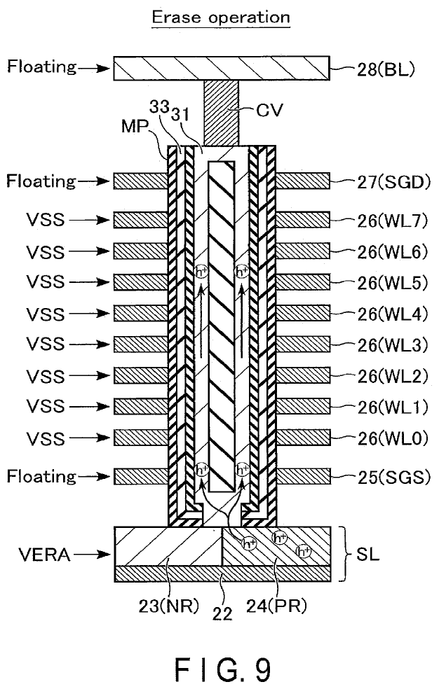

FIG. 9 shows an example of hole behavior in the erase operation of the semiconductor memory device 1 according to the first embodiment. As shown in FIG. 9, in the erase operation, for example, the bit line BL and the select gate lines SGD and SGS are each brought into a floating state, an erase voltage VERA is applied to the source line SL, and a voltage VSS is applied to the word line WL. The erase voltage VERA is higher than VSS and is a high voltage for use in the erase operation.

In the erase operation, when the foregoing voltages are applied, the voltage of the channel (semiconductor layer 31) increases based on the voltage of the source line SL, and the voltage of each of the bit line BL and the select gate lines SGD and SGS increases in accordance with the increase of the voltage of the channel. When the voltage of the channel increases, holes (h⁺) move into the channel from the P-type semiconductor region PR of the source line SL. That is, in the erase operation of the semiconductor memory device 1 according to the first embodiment, the holes are supplied to the channel of the NAND string NS from the P-type semiconductor region PR (P-type semiconductor layer 24).

Since, in the erase operation, VSS is applied to the word line WL, a difference in voltage is caused between the control gate and channel of the memory cell transistor MT. In other words, the gradient of voltage is formed between the high voltage of the channel and the low voltage of the word line WL. Then, the holes are injected from the channel into the charge storage layer (insulating film 33), and the electrons held in the charge storage layer based upon the written data and the injected holes are recombined, with the result that the threshold voltage of the memory cell transistor MT lowers. As described above, the semiconductor memory device 1 according to the first embodiment can erase the data from the memory cell transistor MT.

### [1-3] Advantages of First Embodiment

The semiconductor memory device 1 according to the first embodiment described above can improve in its erase characteristics. The following is a detailed description of the advantages of the semiconductor memory device 1 according to the first embodiment.

In a semiconductor memory device including memory cells stacked in three dimensions, for example, a stacked interconnect structure including a source line SL, a select gate line SGS, a word line WL and a select gate line SGD is provided above the semiconductor substrate. A memory pillar MP is provided to penetrate the stacked interconnect structure above the source line SL and is electrically connected to the lowermost source line SL. In a semiconductor memory device having a structure in which a memory cell array is provided above the semiconductor substrate, for example, a source line SL is formed by a conductive layer including a semiconductor layer.

The semiconductor memory device performs a read operation by causing an electronic current to flow through a channel in the memory pillar MP. When the electron current is used for the read operation, for example, a semiconductor layer doped with N-type impurities such as phosphorus is used as a source line SL in order to supply electrons to the channel in the memory pillar MP. When a semiconductor layer doped with N-type impurities is used as a source line SL, no holes can be injected into the channel in the memory pillar MP from the source line SL during erase operation.

To inject holes into the channel, it is conceivable to use gate-induced-drain-leakage (GIDL) during erase operation. If GIDL is used during erase operation, for example, an erase voltage VERA is applied to the source line SL, and a high electric field region is formed in the lower portion of the memory pillar MP. With the GIDL, holes are generated in the vicinity of, e.g. the select transistor ST2 and then injected into the channel in the memory pillar MP.

However, the holes generated by the GIDL are greatly influenced by variations of diffusion of impurities in a semiconductor layer used as a source line SL. Furthermore, the variations of the number of holes generated by the GIDL are likely to cause lack of holes during the erase operation and decrease the amount of reduction in the threshold voltage of the memory cell transistor MT. It is therefore difficult to stabilize erase characteristics in the erase operation using GIDL.

Therefore, in the semiconductor memory device 1 according to the first embodiment, the semiconductor layer used as a source line SL includes N-type and P-type semiconductor regions NR and PR arranged in stripes. The bottom of the semiconductor layer 31 (channel) in each memory pillar MP is connected to each of the N-type and P-type semiconductor regions NR and PR.

As a result, in the semiconductor memory device 1 according to the first embodiment, the N-type semiconductor region NR (semiconductor layer 23) can supply electrons to the channel during the read operation and the P-type semiconductor region PR (semiconductor layer 24) can supply holes to the channel during the erase operation. That is, the structure of the source line SL in the semiconductor memory device 1 according to the first embodiment can generate both electrons for use in the read operation and holes for use in the erase operation.

The supply of holes in the erase operation of the semiconductor memory device 1 according to the first embodiment is more stable than when using the GIDL because of the use of holes in the P-type semiconductor region PR. Thus, the semiconductor memory device 1 according to the first embodiment can suppress the degradation of erase characteristics due to lack of holes during erase operation and thus improve the erase characteristics.

### [2] Second Embodiment

The semiconductor memory device 1 according to a second embodiment includes an N-type semiconductor region NR and a P-type semiconductor region PR which are similar to those of the first embodiment and also includes two NAND strings NS in each memory pillar MP. Hereinafter, the semiconductor memory device 1 according to the second embodiment will be described, excluding the same points as those in the first embodiment.

### [2-1] Configuration of Semiconductor Memory Device 1

[2-1-1] Circuit Configuration of Memory Cell Array 10

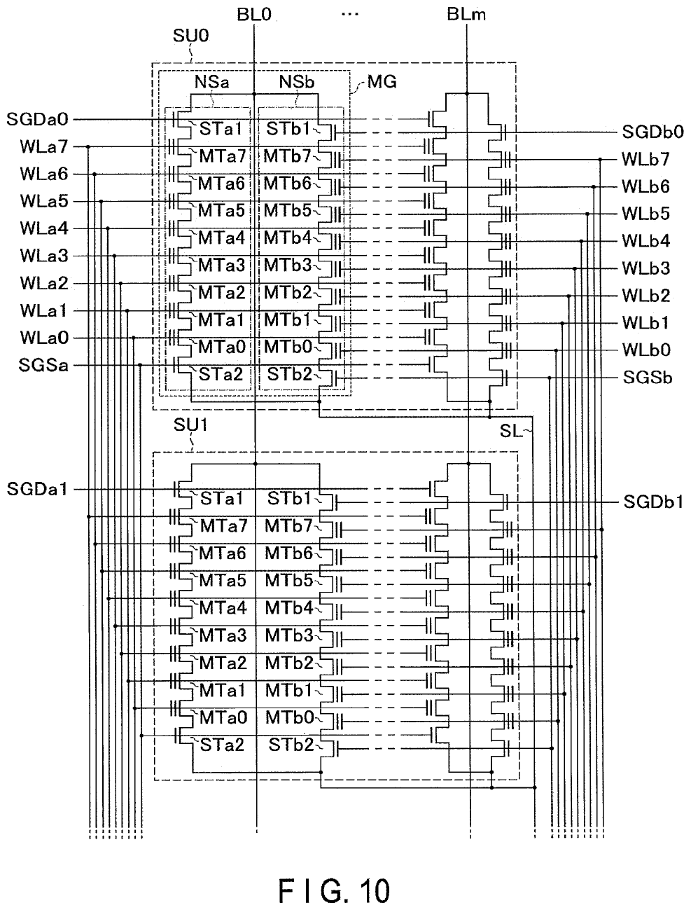

FIG. 10 shows an example of a circuit configuration of a memory cell array 10 of the semiconductor memory device 1 according to the second embodiment, extracting two string units SU0 and SU1 included in the memory cell array 10. As shown in FIG. 10, each string unit SU includes a plurality of memory groups MG.

Each of the memory groups MG includes two NAND strings NSa and NSb. The NAND string NSa includes, for example, memory cell transistors MTa0 to MTa7 and select transistors STa1 and STa2. The NAND string NSb includes, for example, memory cell transistors MTb0 to MTb7 and select transistors STb1 and STb2.

Each of the memory cell transistors MTa and MTb functions like the memory cell transistor MT. Each of the select transistors STa1 and STb1 functions like the select transistor ST1. Each of the select transistors STa2 and STb2 functions like the select transistor ST2. The drains of the select transistors STa1 and STb1 included in the same memory group MG are connected to the same bit line BL.

In the NAND string NSa, the memory cell transistors MTa0 to MTa7 are connected in series. The drain of the select transistor STa1 is connected to its associated bit line BL and the source thereof is connected to one end of the series-connected memory cell transistors MTa0 to MTa7. The drain of the select transistor STa2 is connected to the other end of the series-connected memory cell transistors MTa0 to MTa7. The source of the select transistor STa2 is connected to the source line SL.

In the NAND string NSb, the memory cell transistors MTb0 to MTb7 are connected in series. The drain of the select transistor STb1 is connected to its associated bit line BL and the source thereof is connected to one end of the series-connected memory cell transistors MTb0 to MTb7. The drain of the select transistor STb2 is connected to the other end of the series-connected memory cell transistors MTb0 to MTb7. The source of the select transistor STb2 is connected to the source line SL.

In the same block BLK, the control gates of the memory cell transistors MTa0 to MTa7 are connected to their respective word lines WLa0 to WLa7. The gates of the select transistors STa1 in the string units SU0 and SU1 are connected to their respective select gate lines SGDa0 and SGDa1. The gate of the select transistor STa2 is connected to the select gate line SGSa.

In the same block BLK, the control gates of the memory cell transistors MTb0 to MTb7 are connected to their respective word lines WLb0 to WLb7. The gates of the select transistors STb1 in the string units SU0 and SU1 are connected to their respective select gate lines SGDb0 and SGDb1. The gate of the select transistor STb2 is connected to the select gate line SGSb.

In the circuit configuration of the memory cell array 10 described above, the bit line BL is shared by the NAND strings NSa and NSb to which the same column address is assigned in each string unit SU. The source line SL is shared among, for example, a plurality of blocks BLK. In addition, the word lines WLa and WLb, select gate lines SGDa and SGDb and select gate lines SGSa and SGSb are controlled independently by the row decoder module 15.

[2-1-2] Configuration of Memory Cell Array 10

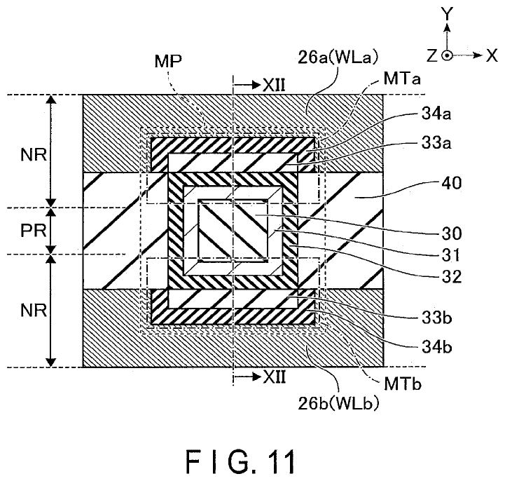

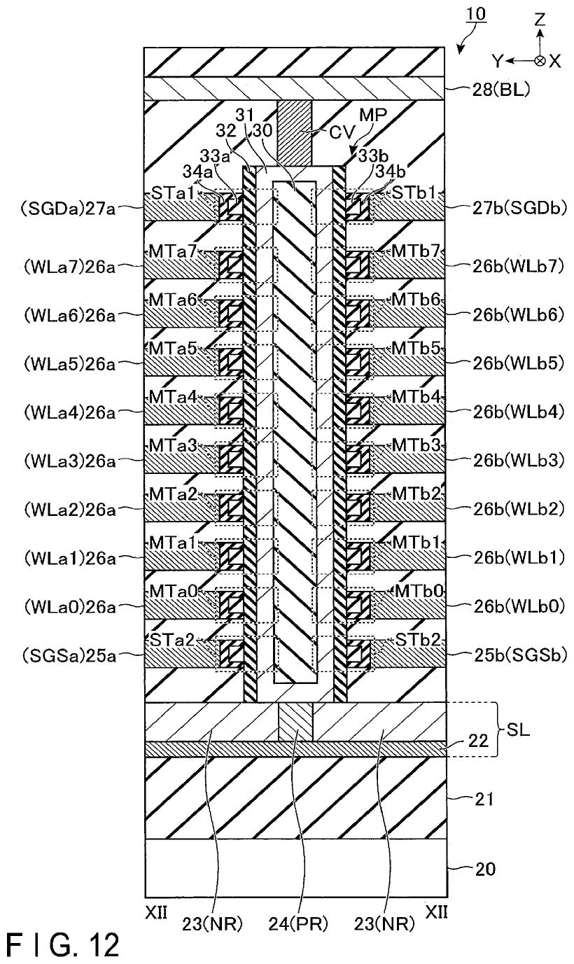

An example of the configuration of the memory cell array 10 of the semiconductor memory device 1 according to the second embodiment will be described below with reference to FIGS. 11 and 12. FIG. 11 shows an example of the sectional structure of the memory pillar MP which is parallel to the surface of the semiconductor substrate 20 and which includes the word lines WLa and WLb. FIG. 12 is a sectional view along line XII-XII of FIG. 11, showing an example of the sectional structure of the memory pillar MP which is perpendicular to the surface of the semiconductor substrate 20 and which includes a stacked interconnect structure. As shown in FIGS. 11 and 12, the memory cell array 10 includes a dividing layer 40 and conductive layers 25a, 25b, 26a, 26b, 27a and 27b.

The dividing layer 40 is provided to extend in, for example, the X direction and includes a plurality of insulator regions arranged along the X direction. The dividing layer 40 divides the stacked word lines WL and select gate lines SGS and SGD. The conductive layers 26 corresponding to the word lines WL are each divided into conductive layers 26a and 26b by the dividing layer 40. The conductive layer 25 corresponding to the select gate line SGS is divided into conductive layers 25a and 25b by the dividing layer 40. The conductive layer 27 corresponding to the select gate line SGD is divided into conductive layers 27a and 27b by the dividing layer 40.

For example, the conductive layers 25a, 25b, 26a, 26b, 27a and 27b are provided linearly to extend in the X direction. Then, a plurality of conductive layers 26a are arranged above the conductive layer 25a with an insulator layer therebetween. The conductive layer 27a is provided above the uppermost conductive layer 26a with an insulator layer therebetween. Similarly, a plurality of conductive layers 26b are arranged above the conductive layer 25b with an insulator layer therebetween. The conductive layer 27b is provided above the uppermost conductive layer 26b with an insulator layer therebetween. The conductive layers 26a and 26b correspond to the word lines WLa and WLb, respectively. The conductive layers 25a and 25b correspond to the select gate lines SGSa and SGSb, respectively. The conductive layers 27a and 27b correspond to the select gate lines SGDa and SGDb, respectively.

In addition, the dividing layer 40 includes a portion that is penetrated (divided) by the memory pillar MP between adjacent insulator regions in the X direction. The memory pillar MP that penetrates the dividing layer 40 is opposed to each of the adjacent conductive layers 26a and 26b, each of the adjacent conductive layers 25a and 25b and each of the adjacent conductive layers 27a and 27b. In the second embodiment, the memory pillar MP is, for example, a rectangle in planar view. The memory pillar MP includes a core member 30, a semiconductor layer 31, a tunnel insulating film 32, insulating films 33a and 33b, and block insulating films 34a and 34b.

The core member 30 is provided in the central part of the memory pillar MP to extend in the Z direction. The semiconductor layer 31 covers the core member 30. The tunnel insulating film 32 covers the side of the semiconductor layer 31. The tunnel insulating film 32 is in contact with the dividing layer 40 in the X direction. The insulating film 33a and the block insulating film 34a are provided between the tunnel insulating film 32 and each of the conductive layers 25a, 26a and 27a. The insulating film 33b and block insulating film 34b are provided between the tunnel insulating film 32 and each of the conductive layers 25b, 26b and 27b. The insulating films 33a and 33b are in contact with the tunnel insulating film 32. The insulating films 33a and 33b are covered with the block insulating films 34a and 34b, respectively, except for a portion that is in contact with the tunnel insulating film 32. The block insulating film 34a is in contact with the conductive layer 25a, 26a or 27a. The block insulating film 34b is in contact with the conductive layer 25b, 26b or 27b.

In the second embodiment, the N-type semiconductor region NR and P-type semiconductor region PR are arranged alternately in the Y direction as in the first embodiment. The N-type semiconductor region NR is provided to overlap, for example, the conductive layers 26a and 26b and part of the dividing layer 40, and the P-type semiconductor region PR is provided, for example, immediately below and in parallel to the dividing layer 40. In the second embodiment, therefore, for example, the width of the P-type semiconductor region PR in the Y direction is smaller than that of the N-type semiconductor region NR in the Y direction in the region where the N-type semiconductor region NR and P-type semiconductor region PR are arranged alternately. The semiconductor layer 31 in the memory pillar MP is in contact with adjacent N-type semiconductor layers 23 in the Y direction and a P-type semiconductor layer 24 between these N-type semiconductor layers 23. The N-type semiconductor region NR and P-type semiconductor region PR in the second embodiment can be controlled independently as in the modification to the first embodiment.

Furthermore, in the second embodiment, a columnar contact CV is provided on the top surface of the semiconductor layer 31 in each memory pillar MP as in the first embodiment. One conductive layer 28, i.e. one bit line BL is in contact with the top surface of the contact CV.

In the configuration of the memory pillar MP described above, a portion where the memory pillar MP and the conductive layer 26a (word line WLa) are opposed to each other functions as a memory cell transistor MTa and a portion where the memory pillar MP and the conductive layer 26b (word line WLb) are opposed to each other functions as a memory cell transistor MTb. Similarly, a portion where the memory pillar MP and the conductive layer 25a (select gate line SGSa) are opposed to each other functions as a select transistor STa2 and a portion where the memory pillar MP and the conductive layer 25b (select gate line SGSb) functions as a select transistor STb2. A portion where the memory pillar MP and the conductive layer 27a (select gate line SGDa) are opposed to each other functions as a select transistor STa1 and a portion where the memory pillar MP and the conductive layer 27b (select gate line SGDb) are opposed to each other functions as a select transistor STb1.

In the semiconductor memory device 1 according to the second embodiment, the memory cell transistors MTa and MTb respectively use the insulating films 33a and 33b as charge storage layers. The memory cell transistors MTa and MTb and select transistors STa1, STb1, STa2 and STb2 share the semiconductor layer 31 (channel). A set of select transistors STa1 and STa2 and memory cell transistors MTa0 to MTa7 arranged in the Z direction corresponds to the NAND string NSa. A set of select transistors STb1 and STb2 and memory cell transistors MTb0 to MTb7 arranged in the Z direction corresponds to the NAND string NSb.

Furthermore, in a direction parallel to the surface of the semiconductor substrate 20 (e.g. Y direction), the memory cell transistors MTa0 to MTa7 and select transistors STa1 and STa2 are opposed to the memory cell transistors MTb0 to MTb7 and select transistors STb1 and STb2, respectively. In other words, the memory cell transistors MTa0 to MTa7 and select transistors STa1 and STa2 are adjacent to the memory cell transistors MTb0 to MTb7 and select transistors STb1 and STb2, respectively, with a region where the conductive layers 25 to 27 are divided by the dividing layer 40 therebetween. The other configurations of the semiconductor memory device according to the second embodiment are similar to those of the semiconductor memory device 1 according to the first embodiment, their descriptions will be omitted.

### [2-2] Manufacturing Method of Semiconductor Memory Device 1

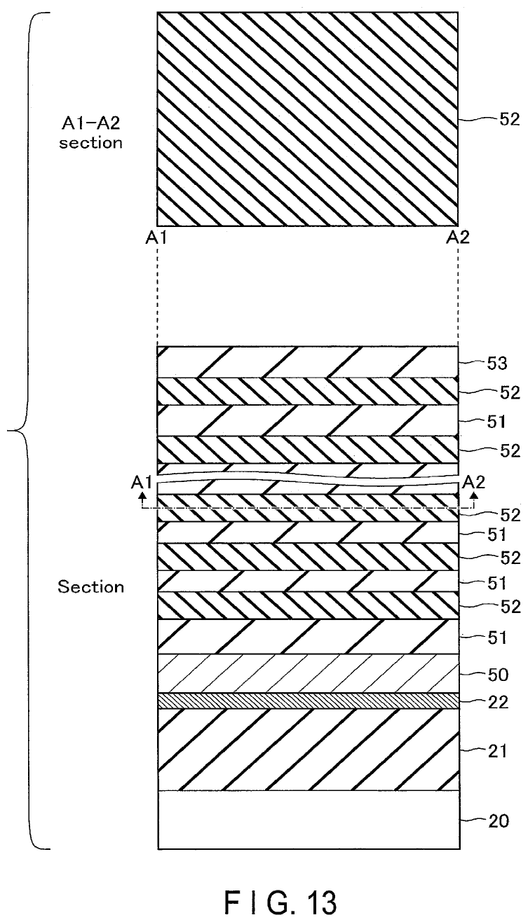

Below is a description of an example of a series of manufacturing steps of forming a stacked interconnect structure in the memory cell array 10 in the semiconductor memory device 1 according to the second embodiment. FIGS. 13 to 23 each show an example of a sectional structure in the middle of manufacture of the semiconductor memory device 1 according to the second embodiment. The lower side of each of FIGS. 13 to 23 corresponds to the section of the region shown in FIG. 12, and the upper side of each of FIGS. 13 to 23 corresponds to the section along line A1-A2 in each of the figures.

First, a plurality of sacrificial members 52 corresponding to the stacked interconnect are stacked as shown in FIG. 13. Specifically, an insulator layer 21 including a circuit corresponding to the sense amplifier module 16 is formed on the semiconductor substrate 20. A conductive layer 22 is stacked on the insulator layer 21, and a semiconductor layer 50 is stacked on the conductive layer 22. Insulator layers 51 and sacrificial members 52 are stacked one on another on the semiconductor layer 50. An insulator layer 53 is formed on the uppermost sacrificial member 52. The semiconductor layer 50 is N-type polysilicon doped with, e.g. phosphorus or arsenic. The sacrificial members 52 are, for example, silicon nitride (SiN).

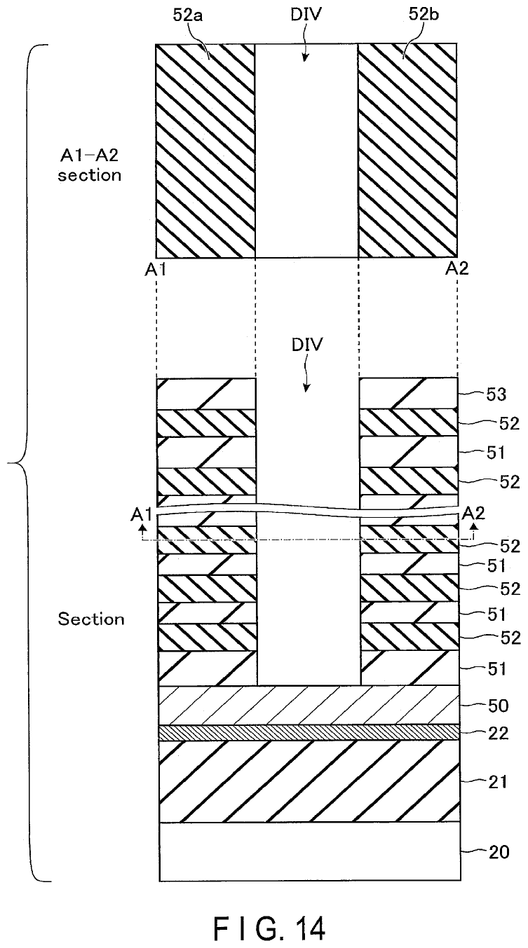

Next, a slit DIV corresponding to the dividing layer 40 is formed as shown in FIG. 14. Specifically, first, a mask with an opened region corresponding to the dividing layer 40 is formed by photolithography or the like. Then, a slit DIV is formed by anisotropic etching using the mask. In this step, the slit DIV divides the insulator layers 51 and 53 and the sacrificial members 52 to expose part of the semiconductor layer 50 to the bottom of the slit DIV. Each of the sacrificial members 52 is divided into sacrificial members 52a and 52b by the slit DIV. The anisotropic etching in this step is, for example, reactive ion etching (RIE).

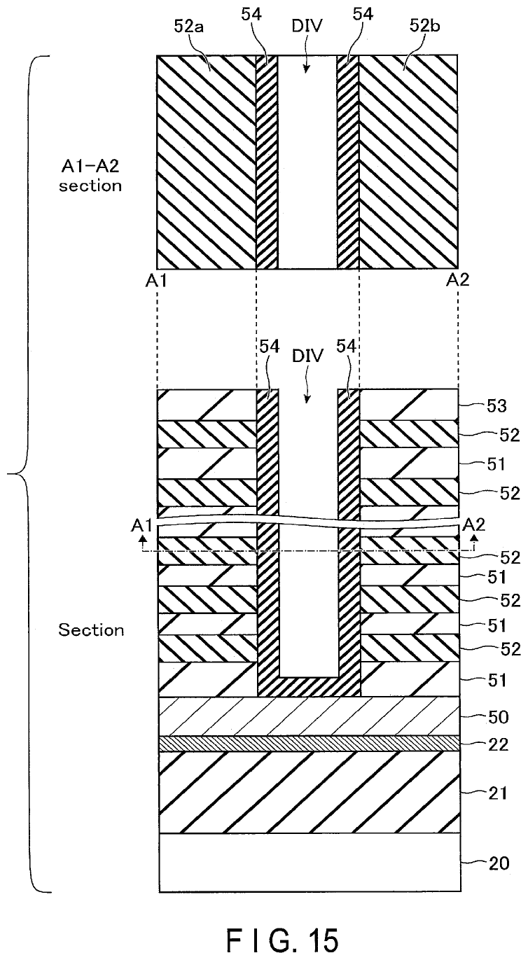

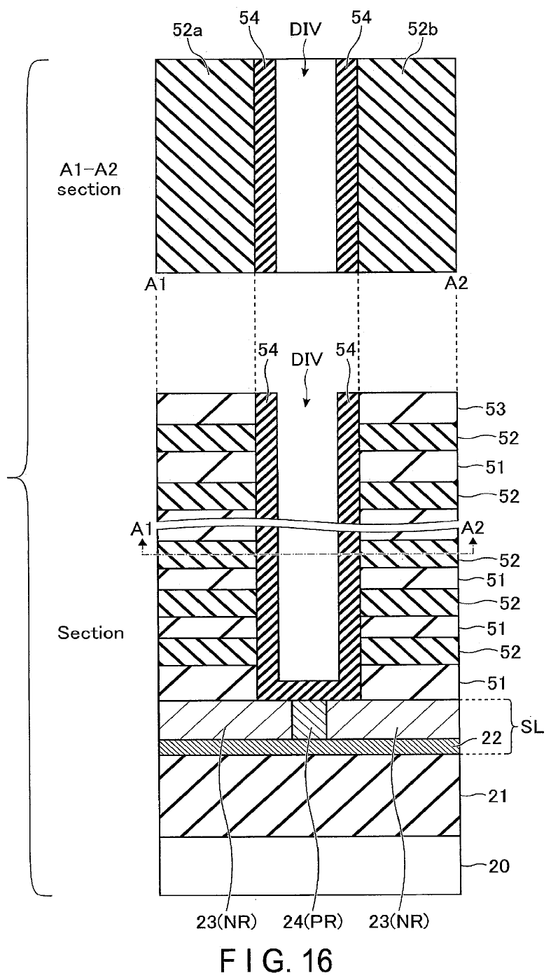

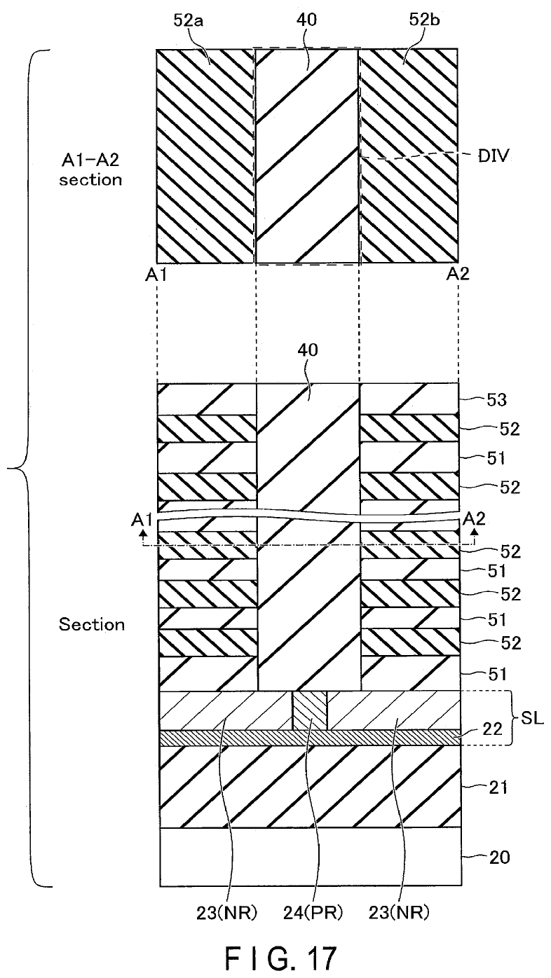

Next, an N-type semiconductor region NR and a P-type semiconductor region PR are formed by ion implantation using the slit DIV. Specifically, first, an insulating film 54 is formed on the side and bottom of the slit DIV as shown in FIG. 15. Then, ion implantation is performed through the insulating film 54 to implant ions into the semiconductor layer 50 located on the bottom of the slit DIV. As the ions implanted into the semiconductor layer 50, for example, boron (B) is used. Thus, as shown in FIG. 16, a p-type semiconductor layer 24, i.e. the P-type semiconductor region PR is formed on the bottom of the slit DIV. Then, a region into which no ions are implanted in the semiconductor layer 50 in this step corresponds to an N-type semiconductor layer 23, i.e. the N-type semiconductor region NR. The insulating film 54 formed in this step is removed after the ion implantation is performed. After that, an insulating film is embedded in the slit DIV and its top surface is flattened by, for example, chemical mechanical polishing (CMP). The dividing layer 40 is thus formed in the slit DIV as shown in FIG. 17.

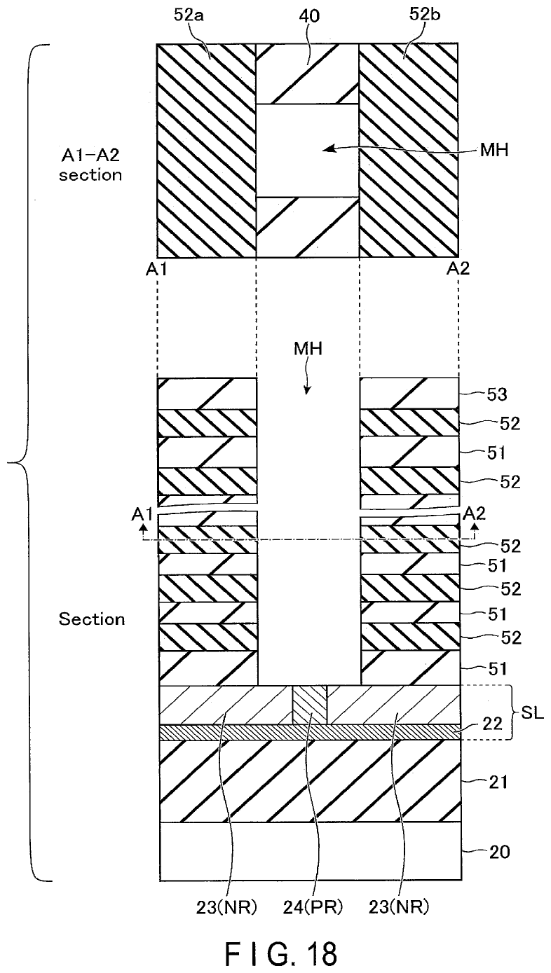

Next, as shown in FIG. 18, a memory hole MH corresponding to the memory pillar MP is formed. Specifically, first, a mask with an opened region corresponding to the memory pillar MP is formed by photolithography or the like. Then, a memory hole MH is formed by anisotropic etching using the mask. In this step, the memory hole MH penetrates the dividing layer 40. Then, the sides of the sacrificial members 52a and 52b, which are adjacent to each other with the dividing layer 40 therebetween, are exposed to the side of the memory hole MH, and adjacent N-type semiconductor layers 23 and the P-type semiconductor layer 24 between these N-type semiconductor layers 23 are partly exposed to the bottom of the memory hole MH. The anisotropic etching in this step is, for example, RIE. In the etching of this step, the insulator layers 51 and 53 and the sacrificial members 52a and 52b may be partly removed.

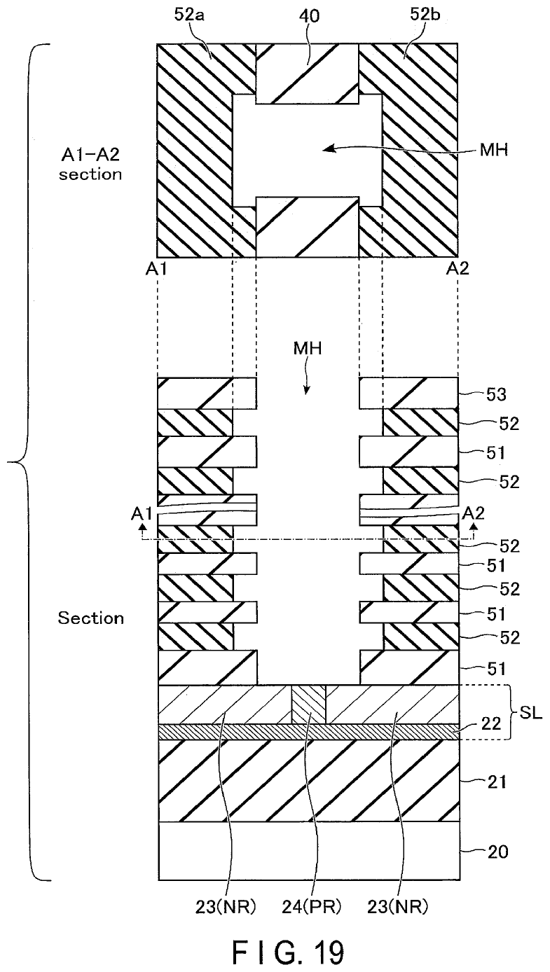

Next, wet etching is performed using the memory hole MH to remove part of each of the sacrificial members 52a and 52b exposed to the side of the memory hole MH. Thus, as shown in FIG. 19, a side portion of the memory hole MH from which the sacrificial members 52a and 52b are removed, is recessed. Hereinafter, the side portion from which the sacrificial members 52a and 52b are removed in this step will be referred to as a recess portion.

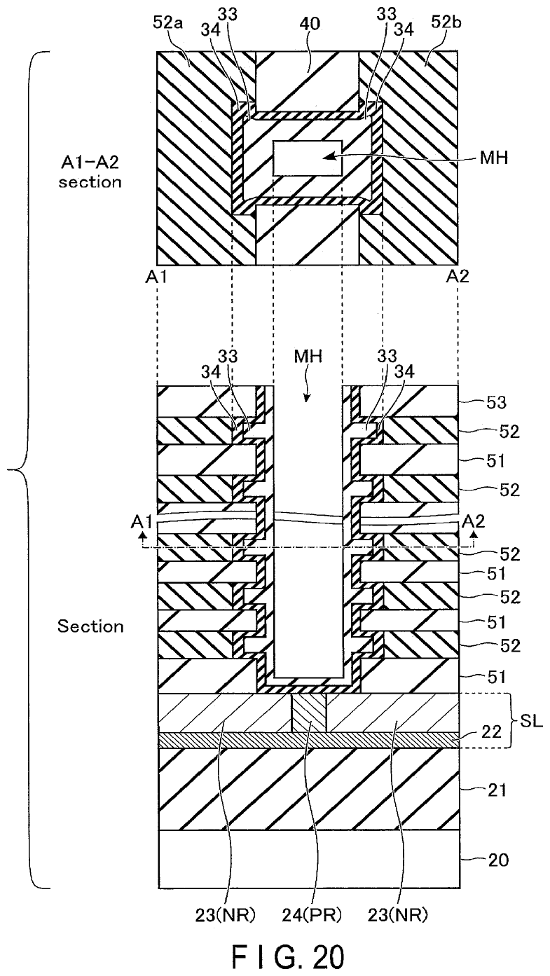

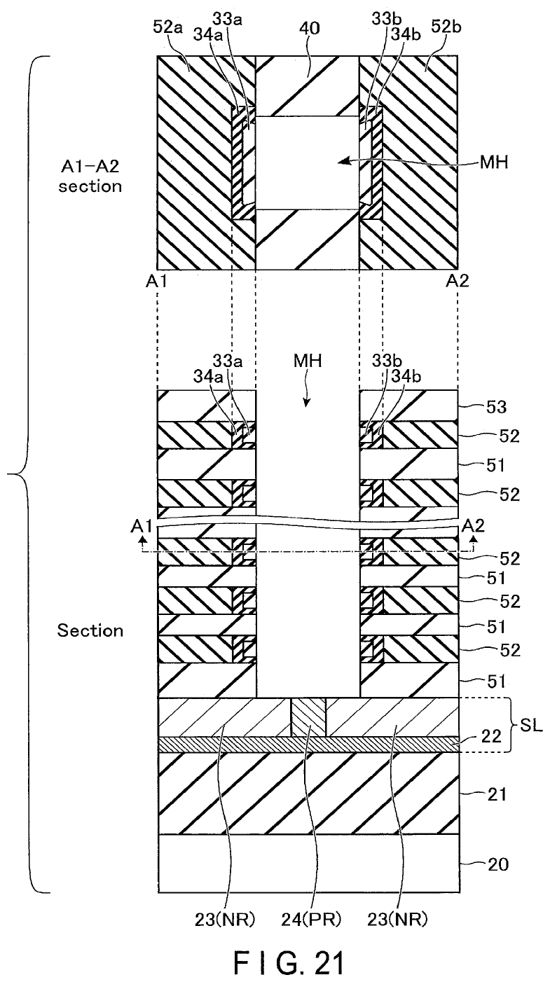

Next, a memory pillar MP is formed using the memory hole MH. Specifically, first, a block insulating film 34 and an insulating film 33 are formed in order as shown in FIG. 20. In this step, the block insulating film 34 is formed so as not to fill the recess portion and the insulating film 33 is formed so as to fill the recess portion. Then, as shown in FIG. 21, the insulating film 33 and the block insulating film 34 are removed from that portion of the memory hole MH from which the recess portion is excluded. Thus, a set of block insulating film 34a and insulating film 33a which are in contact with the sacrificial member 52a and a set of block insulating film 34b and insulating film 33b which are in contact with the sacrificial member 52b are formed.

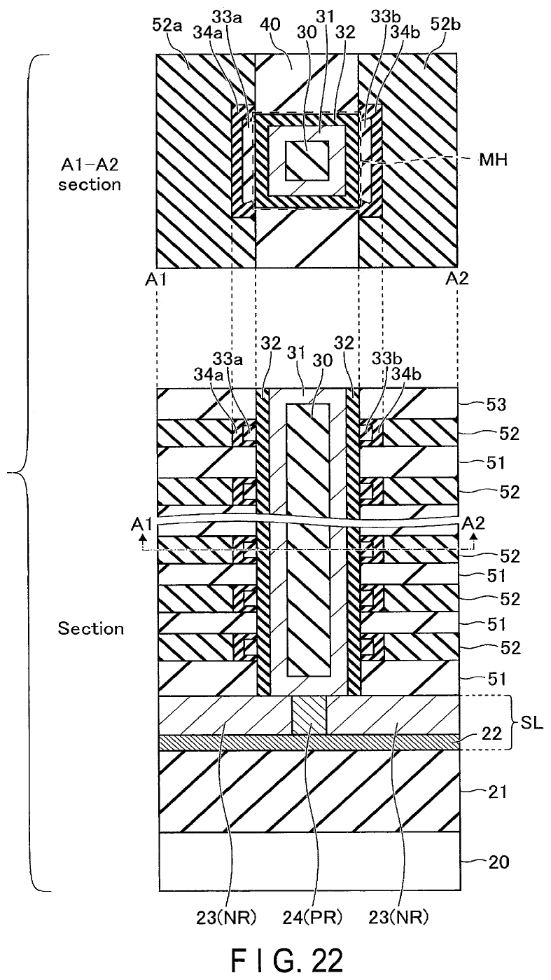

Thereafter, a tunnel insulating film 32, semiconductor layer 31 and a core member 30 are formed in order on the side and bottom of the memory hole MH and on the top surface of the insulating layer 53, and the core member 30 is embedded in the memory hole MH. In this step, the tunnel insulating film 32 is removed from the bottom of the memory hole MH before the semiconductor layer 31 is formed, and the semiconductor layer 31 is formed in contact with the N-type semiconductor layer 23 and P-type semiconductor layer 24 which are exposed to the bottom of the memory hole MH. Then, part of the core member 30 is removed from the top of the memory hole MH, and a semiconductor material (semiconductor layer 31) is embedded in space formed by removing part of the core member 30. In this step, the tunnel insulating film 32 and the semiconductor layer 31 remaining on a layer that is higher than the insulator layer 53, are removed by, for example, CMP. Thus, a structure corresponding to the memory pillar MP is formed in the memory hole MH, as shown in FIG. 22.

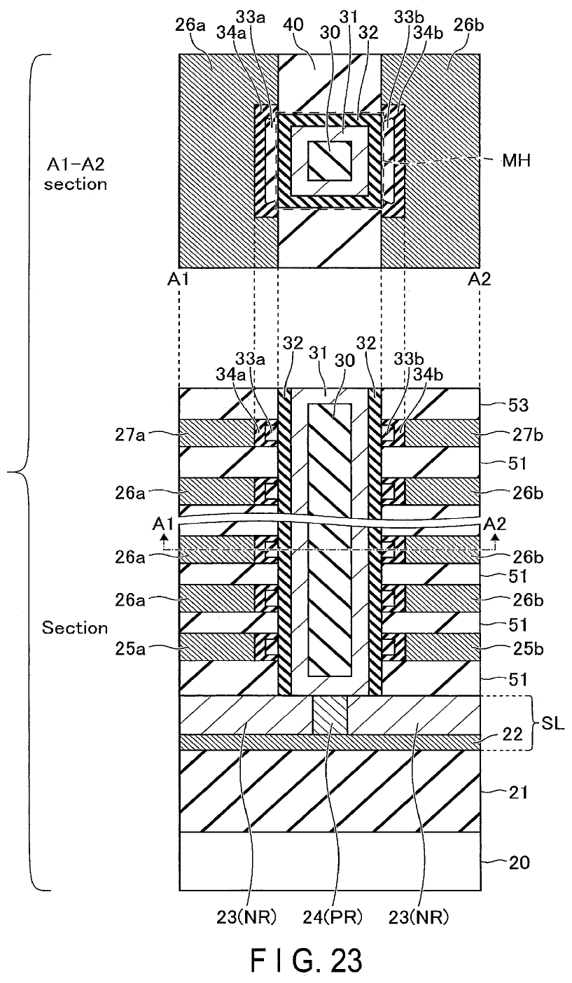

Next, a stacked interconnect substitution process is performed. Specifically, first, a slit or a hole is formed, the sacrificial members 52a and 52b being exposed to the side of the slit or hole. The sacrificial members 52a and 52b are removed by etching through the slit or hole. A conductor is embedded in space formed by removing the sacrificial members 52a and 52b. Thus, the conductive layers 25a, 25b, 26a, 26b, 27a and 27b are formed as shown in FIG. 23. After the conductive layers 25a, 25b, 26a, 26b, 27a and 27b are formed, the slit or hole formed in this step is filled with, for example, an insulator.

Through the foregoing manufacturing steps of the semiconductor memory device 1 according to the second embodiment, the memory pillar MP, the N-type semiconductor region NR and P-type semiconductor region PR corresponding to the source line SL, and the word lines WLa and WLb and select gate lines SGSa, SGSb, SGDa and SGDb, which are connected to the memory pillar MP, are formed.

The foregoing manufacturing steps are only an example, and another step may be inserted between the manufacturing steps. In the semiconductor memory device 1 according to the second embodiment, the step of forming the conductive layer 22 may be omitted. In this case, after the insulator layer 21 is formed, the semiconductor layer 50 is formed on the insulator layer 21. The other manufacturing steps are the same as described above.

### [2-3] Operation of Semiconductor Memory Device 1

The read operation and erase operation of the semiconductor memory device 1 according to the second embodiment will be described below. In order to describe the operations, a portion corresponding to one memory pillar MP shown in FIG. 12 is extracted, and the drawings are used to illustrate one example of a voltage applied to each of the source line SL, bit line BL, word line WL, and select gate lines SGD and SGS at a certain time and the behavior of electrons or holes passing through the memory pillar MP.

In each of the read and erase operations described below, it is assumed that the voltage of each of the word lines WLa and WLb and the select gate lines SGDa, SGDb, SGSa and SGSb is controlled by the row decoder module 15. The NAND string NSa or NSb including the selected memory cell transistor MT will be referred to as a select string, and the NAND string NSa or NSb not including the selected memory cell transistor MT will be referred to as a non-select string.

(Read Operation)

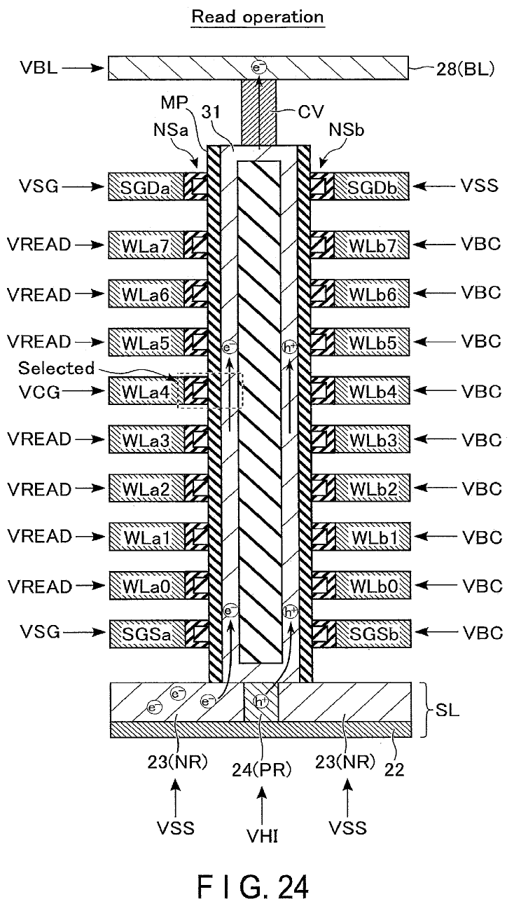

FIG. 24 shows an example of electron and hole behavior in the read operation of the semiconductor memory device 1 according to the second embodiment. In the example shown in FIG. 24, the memory cell transistor MT in the NAND string NSa is selected. As shown in FIG. 24, in the read operation, for example, a voltage VBL is applied to the bit line BL, a voltage VSS is applied to the N-type semiconductor region NR, and a voltage VHI is applied to the P-type semiconductor region PR. Voltages VSG, VSG, VCG and VREAD are respectively applied to the select gate line SGDa, the select gate line SGSa, the select word line WLa and the non-select word line WLa, which correspond to the select string. Voltages VSS, VBC and VBC are respectively applied to the select gate line SGDb, the select gate line SGSb and the word line WLb, which correspond to the non-select string. For example, the voltage VIII is higher than VSS and makes it possible to supply holes to the non-select string during the read operation. The voltage VBC is lower than VSS and is, for example, a negative voltage.

In the read operation, when the foregoing voltages are applied, each transistor in the select string operates as an NMOS transistor. In the select string, the select transistor STa1 connected to the select gate line SGDa, the select transistor STa2 connected to the select gate line SGSa, and the memory cell transistor MTa connected to the non-select word line WLa are turned on, and the select memory cell connected to the select word line WLa is turned on or off based on data to be stored therein. FIG. 24 shows an example of a case where the select memory cell (memory cell transistor MTa4) is turned on.

During the on state of the select memory cell, current flows through the channel of the NAND string NSa (semiconductor layer 31 in the memory pillar MP) between the N-type semiconductor region NR of the source line SL and the bit line BL. Specifically, electrons (e⁻) contained in the N-type semiconductor region NR of the source line SL move toward the bit line BL whose voltage is higher than that of the N-type semiconductor region NR through the semiconductor layer 31 in the select string.

On the other hand, in the read operation, when the foregoing voltages are applied, each transistor in the non-select string operates as a PMOS transistor. In the non-select string, the select transistor STb1 connected to the select gate line SGDb is turned off, and the select transistor STb2 connected to the select gate line SGSb and the memory cell transistor MTb connected to the word line WLb are turned on.

Since a voltage gradient is formed between the P-type semiconductor region PR and the channel of the non-select string, holes (h⁺) move into the channel of the NAND string NSb from the P-type semiconductor region PR of the source line SL. That is, in the read operation of the semiconductor memory device 1 according to the second embodiment, holes are supplied to the non-select string NS from the P-type semiconductor region PR (P-type semiconductor layer 24). Then, the voltage VBC is, for example, a negative voltage and thus the holes in the channel of the non-select string gather in the vicinity of the memory cell transistor MTb.

In the read operation of the semiconductor memory device 1 according to the second embodiment, the select string and the non-select string operate as described above. When the voltage of the bit line BL varies with the state of the select memory cell, the sense amplifier module 16 determines the threshold voltage of the memory cell transistor MT based on the voltage of the bit line BL. As described above, the semiconductor memory device 1 according to the second embodiment can read data out of the select memory cell.

(Erase Operation)

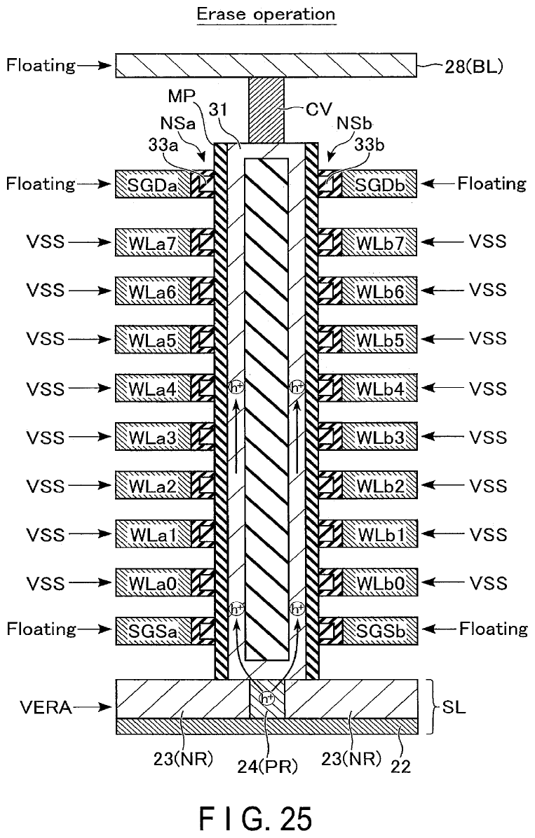

FIG. 25 shows an example of hole behavior in the erase operation of the semiconductor memory device 1 according to the second embodiment. As shown in FIG. 25, in the erase operation, for example, the bit line BL and the select gate lines SGDa, SGDb, SGSa and SGSb are each brought into a floating state, an erase voltage VERA is applied to the source line SL, and a voltage VSS is applied to each of the word lines WLa and WLb.

In the erase operation, when the foregoing voltages are applied, the voltage of the channel (semiconductor layer 31) increases based on the voltage of the source line SL, and the voltage of each of the bit line BL and the select gate lines SGDa, SGDb, SGSa and SGSb increases in accordance with the increase of the voltage of the channel. When the voltage of the channel increases, holes (h⁺) move into the channel from the P-type semiconductor region PR of the source line SL. That is, in the erase operation of the semiconductor memory device 1 according to the second embodiment, the holes are supplied to the channel of each of the NAND strings NSa and NSb from the P-type semiconductor region PR (P-type semiconductor layer 24).

Since, in the erase operation, the voltage VSS is applied to each of the word lines WLa and WLb, a difference in voltage is caused between the control gate and channel of each of the memory cell transistors MTa and MTb. In other words, the gradient of voltage is formed between the high voltage of the channel and the low voltage of the word line WL, as in the first embodiment. Then, the holes are injected from the channel into the charge storage layers (insulating films 33a and 33b), and the electrons held in the charge storage layer based upon the written data and the injected holes are recombined, with the result that the threshold voltage of each of the memory cell transistors MTa and MTb lowers. As described above, the semiconductor memory device 1 according to the second embodiment can erase the data from the memory cell transistors MTa and MTb.

### [2-4] Advantages of Second Embodiment

The semiconductor memory device 1 according to the second embodiment described above can suppress erroneous read. The following is a detailed description of the advantages of the semiconductor memory device 1 according to the second embodiment.

In a semiconductor memory device including memory cells stacked in three dimensions, it is conceivable to divide and operate the memory pillar MP in planar view in order to improve the storage density. For example, when the charge storage layer of the memory pillar MP is divided into two layers in the Y direction and the word line WL is divided into two word lines corresponding to the two layers, two NAND strings NSa and NSb are formed in the memory pillar MP.

In the read operation of the semiconductor memory device as described above, for example, the memory pillar MP includes a select string including a memory cell transistor MT (select memory cell) from which data is to be read and a non-select string including no select memory cells. The select string and non-select string are connected to a common bit line BL.

To read data out of the select memory cell in the above case, a current path between the source line SL and the bit line BL in the non-select string is blocked. For example, the current path in the non-select string can be blocked by turning off the select transistors ST1 and ST2 in the non-select string. Thus, the semiconductor memory device can cause current to flow through only the select string and can perform a read operation for the select memory cell.

In the read operation of the semiconductor memory device described above, it is conceivable that erroneous read is caused by interference effect between the select memory cell and its opposed memory cell transistor MT (hereinafter referred to as a rear memory cell). Specifically, an electric field is generated in the charge storage layer (insulating film 33b) of the rear memory cell in accordance with data held in the rear memory cell. The electric field generated in the rear memory cell changes an apparent threshold voltage of the select memory cell, with the result that erroneous read is likely to be caused.

In the semiconductor memory device 1 according to the second embodiment, therefore, the memory pillar MP is divided and as in the first embodiment, the bottom of the memory pillar MP is connected to each of the N-type semiconductor region NR and P-type semiconductor region PR and the N-type semiconductor region NR and P-type semiconductor region PR can be controlled independently. In the semiconductor memory device 1 according to the second embodiment, in the read operation, for example, a positive voltage is applied to the P-type semiconductor region PR and for example, a negative voltage is applied to the word line connected to the rear memory cell opposed to the select memory cell.

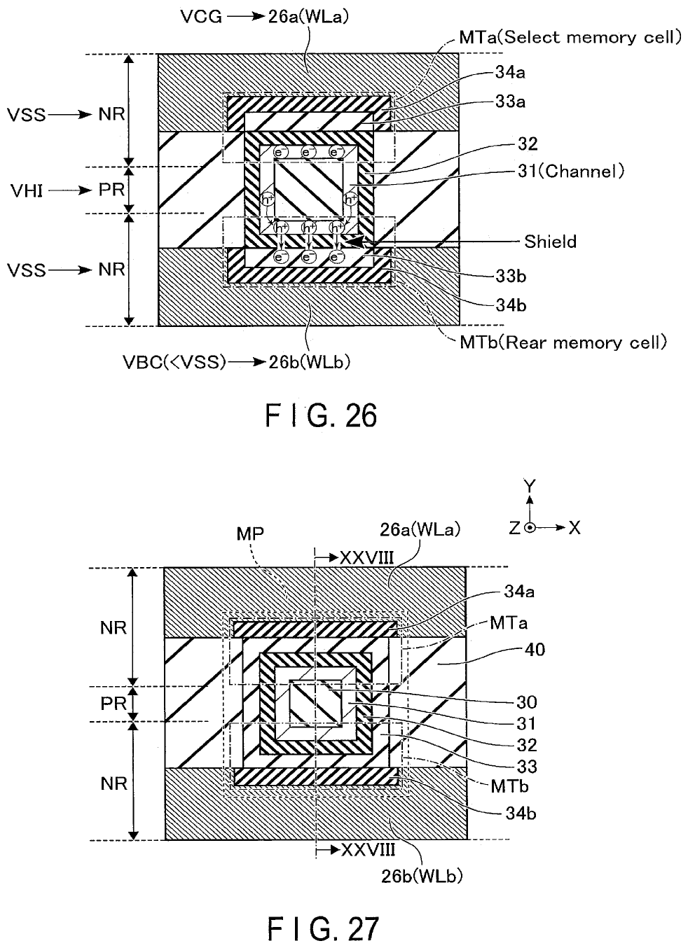

FIG. 26 shows an example of electron and hole behavior in the read operation of the semiconductor memory device 1 according to the second embodiment. FIG. 26 also shows a sectional structure of the memory pillar MP including a select memory cell and a non-select memory cell, in which the memory cell transistor MTa is selected and the memory cell transistor MTb is not selected.

As shown in FIG. 26, in the read operation of the semiconductor memory device 1 according to the second embodiment, a read voltage VCG is applied to the select word line WLa, and the voltage VBC that is lower than, e.g. the voltage VSS is applied to the non-select word line WLb, the voltage VSS is applied to the N-type semiconductor region NR, and the voltage VHI is applied to the P-type semiconductor region PR.

Electrons are supplied from the N-type semiconductor region NR into the channel of the memory cell transistor MTa, i.e. the channel region corresponding to the select string. On the other hand, holes supplied from the P-type semiconductor region PR are attracted to the channel of the memory cell transistor MTb, i.e. the channel region corresponding to the non-select string. That is, the holes supplied from the P-type semiconductor region PR gather between the channel of the select memory cell and the charge storage layer of the rear memory cell.

In the semiconductor memory device 1 according to the second embodiment, therefore, the electric field from the charge storage layer in the rear memory cell to the selected memory cell during the read operation can be shielded by the holes gathered in the channel of the rear memory cell. As a result, the semiconductor memory device 1 according to the second embodiment can suppress the influence of the rear memory cell (non-select string) in the read operation and also suppress erroneous read.

As in the first embodiment, the semiconductor memory device 1 according to the second embodiment can perform an erase operation using the holes generated from the P-type semiconductor region PR. That is, as in the first embodiment, the semiconductor memory device 1 according to the second embodiment can suppress the degradation of erase characteristics due to lack of holes during erase operation and thus improve the erase characteristics.

### [2-5] Modifications to Second Embodiment

The memory pillar MP in the semiconductor memory device 1 according to the second embodiment described above may have another configuration. The following are descriptions of the configuration of the memory pillar MP in each of the first to third modifications to the second embodiment.

### First Modification to Second Embodiment

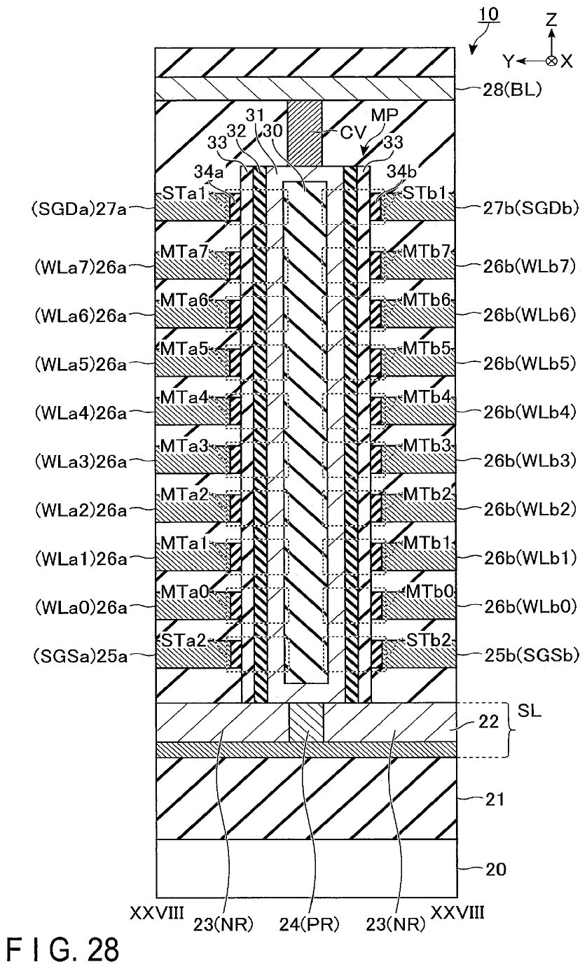

First, an example of the configuration of the memory pillar MP in the semiconductor memory device 1 according to a first modification to the second embodiment will be described with reference to FIGS. 27 and 28. FIG. 27 shows the same region as that of FIG. 11 and FIG. 28 shows the same region as that of FIG. 12. As shown in FIGS. 27 and 28, the memory pillar MP in the first modification is so configured that an insulating film 33 is shared by the transistors in NAND strings NSa and NSb.

Specifically, the insulating film 33 covers the side of a tunnel insulating film 32 in the memory pillar MP. In other words, the insulating film 33 is provided cylindrically to extend in the Z direction. That is, the insulating film (charge storage layer) 33 is continuously provided in the NAND strings NSa and NSb. In this case, too, the semiconductor memory device 1 according to the first modification can store data that varies between the memory cell transistors MTa and MTb opposed to each other in the memory pillar MP and operate in the same manner as in the second embodiment.

### Second Modification to Second Embodiment

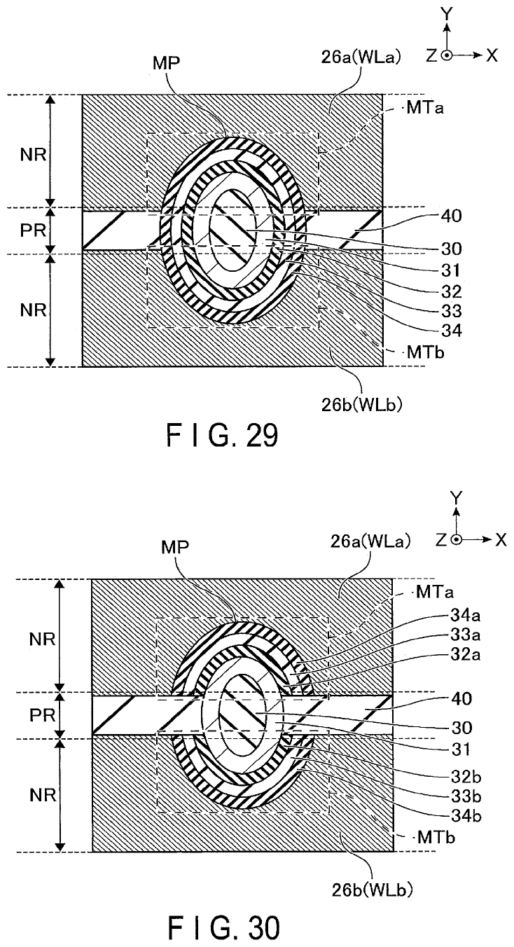

Next, an example of the configuration of the memory pillar MP in the semiconductor memory device 1 according to a second modification to the second embodiment will be described with reference to FIG. 29. FIG. 29 shows the same region as that of FIG. 11. As shown in FIG. 29, the memory pillar MP in the second modification is shaped like an ellipse in planar view. In addition, the memory pillar MP is so configured that an insulating film 33 and a block insulating film 34 are shared by the transistors in NAND strings NSa and NSb.

Specifically, in the memory pillar MP, the insulating film 33 covers the side of a tunnel insulating film 32. The block insulating film 34 covers the side of the insulating film 33. The sectional structure of a region of the memory pillar MP, which corresponds to FIG. 12, in the second modification is similar to that in, for example, the first modification to the second embodiment, excluding the shape of the block insulating film 34 extending in the Z direction. In this case, too, the semiconductor memory device 1 according to the second modification can store data that varies between the memory cell transistors MTa and MTb opposed to each other in the memory pillar MP and operate in the same manner as in the second embodiment.

### Third Modification to Second Embodiment

Next, an example of the configuration of the memory pillar MP in the semiconductor memory device 1 according to a third modification to the second embodiment will be described with reference to FIG. 30. FIG. 30 shows the same region as that of FIG. 11. As shown in FIG. 30, the memory pillar MP in the third modification is shaped like an ellipse in planar view. In addition, the memory pillar MP is so configured that a tunnel insulating film 32, an insulating film 33 and a block insulating film 33 are separated by the transistors in NAND strings NSa and NSb. Specifically, the memory pillar MP includes a core member 30, a semiconductor layer 31, tunnel insulating films 32a and 32b, insulating films 33a and 33b and block insulating films 34a and 34b.

The core member 30 extends in the Z direction and is provided in the central part of the memory pillar MP. The semiconductor layer 31 covers the periphery of the core member 30. The semiconductor layer 31 is also in contact with a dividing layer 40 in the X direction. In the section including word lines WLa and WLb, a tunnel insulating film 32a, an insulating film 33a and a block insulating film 34a are provided between the semiconductor layer 31 and a conductive layer 26a. A tunnel insulating film 32b, an insulating film 33b and a block insulating film 34b are provided between the semiconductor layer 31 and a conductive layer 26b. The tunnel insulating film 32a is sandwiched between the insulating film 33a and the semiconductor layer 31. The block insulating film 34a is sandwiched between the conductive layer 26a and the insulating film 33a. The tunnel insulating film 32b is sandwiched between the insulating film 33b and the semiconductor layer 31. The block insulating film 34b is sandwiched between the conductive layer 26b and the insulating film 33b.

Since the configuration of the memory pillar MP in the section including select gate lines SGDa and SGDb and the configuration of the memory pillar MP in the section including select gate lines SGSa and SGSb are similar to the configuration of the memory pillar MP in the section including the word lines WLa and WLb, their descriptions will be omitted. The sectional structure of a region of the memory pillar MP, which corresponds to FIG. 12, in the third modification is similar to that in the second embodiment, excluding, for example, the configuration that the tunnel insulating film 32 is separated for each of the NAND strings NSa and NSb in the Z direction. In this case, too, the semiconductor memory device 1 according to the third modification can store data that varies between the memory cell transistors MTa and MTb opposed to each other in the memory pillar MP and operate in the same manner as in the second embodiment.

### [3] Other Modifications, etc.

A semiconductor memory device according to an embodiment includes a substrate, a first conductive layer, a plurality of second conductive layers, and a first pillar. The first conductive layer is provided above the substrate. The first conductive layer includes a first N-type semiconductor region and a first P-type semiconductor region arranged in a direction parallel to a surface of the substrate. The second conductive layers are provided above the first conductive layer. The second conductive layers are stacked at intervals in a first direction. The first pillar is provided through the second conductive layers along the first direction. The first pillar includes a first semiconductor layer and a first insulating layer. The first semiconductor layer is in contact with the first N-type semiconductor region and the first P-type semiconductor region. The first insulating layer is provided between the first semiconductor layer and the second conductive layers. Thus, the semiconductor memory device 1 can improve in its erase characteristics.

In the foregoing embodiments, the insulating film is shown as an example of the charge storage layer of the memory cell transistor MT. In the first embodiment, second embodiment and third modification to the second embodiment, a conductor such as a semiconductor and metal may be used as the charge storage layer. That is, the semiconductor memory device 1 according to each of the first embodiment, second embodiment and third modification to the second embodiment may include a memory cell transistor MT of a floating gate type in which the insulating film 33 may be replaced with a conductor. The configuration of the memory cell transistor MT in each of the foregoing embodiments and modifications is designed according to the structure of the charge storage layer in the memory pillar MP. For example, when the charge storage layer is separated for each memory cell transistor MT in both the Y and Z directions in each memory pillar MP, both the insulating film and the conductor can be used as the charge storage layer. The conductor used as the charge storage layer may have a stacked structure using two or more of a semiconductor, metal and an insulator. On the other hand, when the charge storage layer is not separated for each memory cell transistor MT in both the Y and Z directions in each memory pillar MP, an insulating film is used as the charge storage layer. Regardless of whether or not the charge storage layer is separated for each memory cell transistor MT in the Y and Z directions, each of the tunnel insulating film and the block insulating film may be shared by the transistors, or separated for each transistor, in the NAND strings NSa and NSb in the memory pillar MP. Also, regardless of whether or not the charge storage layer is separated for each memory cell transistor MT in the Y and Z directions, each of the tunnel insulating film and the block insulating film may be separated for each memory cell transistor MT in the Z direction in the memory pillar MP, or may extend in the Z direction in the memory pillar MP.

In the foregoing embodiments, the concentration of N-type impurities (e.g. phosphorus or arsenic) doped with the N-type semiconductor layer 23 is, for example, 10¹⁹ (atoms/cm³) or more. Similarly, the concentration of P-type impurities (e.g. boron) doped with the P-type semiconductor layer 24 is, for example, 10¹⁹ (atoms/cm³) or more. When the P-type semiconductor layer 24 is formed by ion implantation into the semiconductor layer 50 corresponding to the N-type semiconductor layer 23, the concentration of P-type impurities in the P-type semiconductor layer 24 is set higher than that of N-type impurities in the P-type semiconductor layer 24. Since, furthermore, the N-type semiconductor layer 23 and the P-type semiconductor layer 24 are formed adjacent to each other, impurities are likely to diffuse between the N-type semiconductor layer 23 and the P-type semiconductor layer 24 by heat treatment in the manufacturing step. Thus, the boundary of the N-type semiconductor layer 23 and the P-type semiconductor layer 24 need not be clarified, with the result that a concentration gradient of impurities may be formed in a boundary portion of adjacent N-type and P-type semiconductor layers 23 and 24.

In the second embodiment, the N-type and P-type semiconductor layers 23 and 24 are arranged alternately in the Y direction as in the first embodiment. However, the embodiment is not limited to the arrangement. In the read operation of the semiconductor memory device 1, the N-type semiconductor region NR and the P-type semiconductor region PR can be controlled independently. If electrons can move from the N-type semiconductor region NR to the channel of one of the two NAND strings NSa and NSb in the memory pillar MP and holes can move from the P-type semiconductor region PR to the channel of the other of the NAND strings, the N-type semiconductor layer 23 and the P-type semiconductor layer 24 may be arranged in completely different arrangement.

In the second embodiment, furthermore, the shape of the memory pillar MP is rectangular in planar view, but it need not be completely rectangular in planar view. For example, the corners of the memory pillar MP may be shaped like an arc in planar view or the sides thereof may be rounded.

In the foregoing embodiments, the memory cell array 10 may have another configuration. For example, the memory pillar MP may have a configuration in which two or more pillars are connected in the Z direction. The memory pillar MP may also have a configuration in which a pillar corresponding to the select gate line SGD and a pillar corresponding to the word line WL are connected. The slit SLT may include a plurality of types of insulator. An optional number of bit lines BL may be overlaid on each memory pillar MP.

In the foregoing embodiments, the memory cell array 10 may have one or more dummy word lines between the word line WL0 and the select gate line SGS and between the word line WL7 and the select gate line SGD. When the dummy word lines are provided, dummy transistors whose number corresponds to the number, of dummy word lines are provided between the memory cell transistor MT0 and the select transistor ST2 and between the memory cell transistor MT7 and the select transistor ST1. The dummy transistors have the same configuration as that of the memory cell transistors MT and are not used for storage of data. When two or more memory pillars MP are connected in the Z direction, the memory cell transistors MT close to the connecting portion of the pillars may be used as dummy transistors.

In the foregoing embodiments, the semiconductor memory device 1 has the configuration in which circuits such as the sense amplifier module 16 are provided under the memory cell array 10. However, the embodiments are not limited to the configuration. For example, the semiconductor storage device 1 may have a configuration in which a chip provided with the sense amplifier module 16 and the like and a chip provided with the memory cell array 10 are bonded to each other.

According to the figures used for the descriptions of the above embodiments, the outer diameter of the memory pillar MP does not vary with the layer position. However, the embodiments are not limited thereto. For example, the memory pillar MP may be formed in a tapered shape or a reverse tapered shape and may be formed with its intermediate portion swelled. Similarly, the slit SLT may be formed in a tapered shape or a reverse tapered shape and may be formed with its intermediate portion swelled.

The term “connected” used in the present specification represents an electrical connection and does not exclude, for example, another element through which the electrical connection is made. The term “electrically connected” may include a connection that is made through an insulator if it can operate like an electrically-connected element. The term “columnar” represents a structure provided in a hole formed in the manufacturing step of the semiconductor memory device 1. The term “outer diameter” represents the diameter of an element in a section parallel to the surface of the semiconductor substrate 20.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor memory device comprising:
a substrate;
a first conductive layer provided above the substrate, the first conductive layer including a first N-type semiconductor region and a first P-type semiconductor region arranged in a direction parallel to a surface of the substrate;
a plurality of second conductive layers provided above the first conductive layer, the second conductive layers being stacked at intervals in a first direction; and
a first pillar provided through the second conductive layers along the first direction, the first pillar including a first semiconductor layer and a first insulating layer, the first semiconductor layer being in contact with the first N-type semiconductor region and the first P-type semiconductor region, the first insulating layer being provided between the first semiconductor layer and the second conductive layers.

2. The device of claim 1, further comprising:
an upper conductive layer provided above the second conductive layers and electrically connected to the first semiconductor layer,
wherein:
the first conductive layer is used as a source line;
the second conductive layers are each used as a word line; and
the upper conductive layer is used as a bit line.

3. The device of claim 1, further comprising a controller configured to perform an erase operation,
wherein the controller applies an erase voltage to the first conductive layer and applies a voltage that is lower than the erase voltage to each of the second conductive layers during the erase operation to supply holes to the first semiconductor layer from the first P-type semiconductor region.

4. The device of claim 3, further comprising:
an upper conductive layer provided above the second conductive layers and electrically connected to the first semiconductor layer,
wherein:
the controller is configured to further performer a read operation; and
the controller applies a first voltage to the first conductive layer applies a read voltage to one of the second conductive layers, and applies a voltage that is higher than the first voltage to the upper conductive layer during the read operation to supply electrons to the first semiconductor layer from the first N-type semiconductor region.

5. The device of claim 1, further comprising:
a second pillar that is adjacent to the first pillar, the second pillar including a second semiconductor layer and a second insulating layer, the second semiconductor layer being provided through the second conductive layers along the first direction, the second insulating layer being provided between the second semiconductor layer and the second conductive layers; and
a third pillar that is adjacent to the first pillar and the second pillar, the third pillar including a third semiconductor layer and a third insulating layer, the third semiconductor layer being provided through the second conductive layers along the first direction, the third insulating layer being provided between the third semiconductor layer and the second conductive layers,
wherein:
the first conductive layer further includes a second N-type semiconductor region and a second P-type semiconductor region;
the first N-type semiconductor region, the second N-type semiconductor region, the first P-type semiconductor region and the second P-type semiconductor region are provided to extend along a second direction that intersects the first direction;
the first P-type semiconductor region is provided between the first N-type semiconductor region and the second N-type semiconductor region, and the second N-type semiconductor region is provided between the first P-type semiconductor region and the second P-type semiconductor region; and
the second semiconductor layer is in contact with the first P-type semiconductor region and the second N-type semiconductor region, and the third semiconductor layer is in contact with the second N-type semiconductor region and the second P-type semiconductor region.

6. The device of claim 5, further comprising:
a contact provided to extend along the direction parallel to the surface of the substrate, the contact being in contact with the first N-type semiconductor region, the second N-type semiconductor region, the first P-type semiconductor region and the second P-type semiconductor region.

7. The device of claim 5, further comprising:
a first contact provided to extend along the direction parallel to the surface of the substrate, the first contact being in contact with the first N-type semiconductor region and the second N-type semiconductor region and being isolated from the first P-type semiconductor region and the second P-type semiconductor region; and
a second contact provided to extend along the direction parallel to the surface of the substrate, the second contact being in contact with the first P-type semiconductor region and the second P-type semiconductor region and being isolated from the first N-type semiconductor region and the second N-type semiconductor region.

8. The device of claim 1, wherein:
the first N-type semiconductor region contains one of phosphorus and arsenic; and
the first P-type semiconductor region contains boron.

9. A semiconductor memory device comprising:
a substrate;
a first conductive layer provided above the substrate, the first conductive layer including a first N-type semiconductor region, a second N-type semiconductor region, and a first P-type semiconductor region between the first N-type semiconductor region and the second N-type semiconductor region;
a second conductive layer and a third conductive layer each provided above the first N-type semiconductor region, the second conductive layer and the third conductive layer being stacked to be isolated from each other in a first direction;
a fourth conductive layer and a fifth conductive layer each provided above the second N-type semiconductor region and in a layer that is the same as the second conductive layer and the third conductive layer, the fourth conductive layer and the fifth conductive layer being isolated from each other in the first direction;
a plurality of insulator regions provided between the second conductive layer and the fourth conductive layer and between the third conductive layer and the fifth conductive layer along a second direction that intersects the first direction; and
a first pillar extending along the first direction and provided between the insulator regions, the first pillar including a first semiconductor layer and a first insulating layer, the first semiconductor layer being in contact with the first N-type semiconductor region, the second N-type semiconductor region and the first P-type semiconductor region, the first insulating layer being provided between the first semiconductor layer and the second to fifth conductive layers.

10. The device of claim 9, wherein a portion where the first pillar and the second conductive layer are opposed to each other functions as a first memory cell transistor, a portion where the first pillar and the third conductive layer are opposed to each other functions as a second memory cell transistor, a portion where the first pillar and the fourth conductive layer are opposed to each other functions as a third memory cell transistor, and a portion where the first pillar and the fifth conductive layer are opposed to each other functions as a fourth memory cell transistor.

11. The device of claim 10, further comprising a controller configured to perform a read operation,
wherein during a read operation in which the first memory cell transistor is selected, the controller applies a first voltage to each of the first N-type semiconductor region and the second N-type semiconductor region in the first conductive layer, applies a second voltage that is higher than the first voltage to the first P-type semiconductor region in the first conductive layer, applies a read voltage to the second conductive layer, applies a read pass voltage that is higher than the read voltage to the third conductive layer, and applies a third voltage that is lower than the first voltage to the fourth conductive layer and the fifth conductive layer.

12. The device of claim 11, further comprising:
a sixth conductive layer provided between the first conductive layer and each of the second conductive layer and the third conductive layer; and
a seventh conductive layer provided between the first conductive layer and each of the fourth conductive layer and the fifth conductive layer and in a layer that is the same as the sixth conductive layer, the sixth conductive layer and the seventh conductive layer being isolated from each other,
wherein:
part of the first pillar is provided between the sixth conductive layer and the seventh conductive layer;
a portion where the sixth conductive layer and the first pillar are opposed to each other functions as a first select transistor;
a portion where the seventh conductive layer and the first pillar are opposed to each other functions as a second select transistor; and
the controller applies a fourth voltage that is higher than the first voltage to the sixth conductive layer and applies the third voltage to the seventh conductive layer during the read operation in which the first memory cell transistor is selected.

13. The device of claim 11, wherein at least one of the first N-type semiconductor region and the second N-type semiconductor region to which the first voltage is applied, supplies electrons to a portion of the first semiconductor layer opposed to the second conductive layer during the read operation.

14. The device of claim 13, wherein when the third voltage is applied to the fourth conductive layer and the fifth conductive layer during the read operation, holes gather in a portion of the first semiconductor layer opposed to the fourth conductive layer and the fifth conductive layer to shield an electric field generated from the third memory cell transistor toward the first memory cell transistor.

15. The device of claim 9, wherein the second to fifth conductive layers are each provided to extend along the second direction.

16. The device of claim 15, wherein the first P-type semiconductor region is provided to extend along the second direction between the first N-type semiconductor region and the second N-type semiconductor region.

17. The device of claim 9, further comprising:
an upper conductive layer provided above the second to fifth conductive layers and electrically connected to the first semiconductor layer,
wherein:
the first conductive layer is used as a source line;
the second to fifth conductive layers are each used as a word line; and
the upper conductive layer is used as a bit line.

18. The device of claim 9, further comprising a controller configured to perform an erase operation,
wherein the controller applies an erase voltage to the first conductive layer and applies a voltage that is lower than the erase voltage to each of the second to fifth conductive layers during the erase operation to supply holes to the first semiconductor layer from the first P-type semiconductor region.

19. The device of claim 9, further comprising:
a first contact provided to extend along a third direction that intersects the first direction and the second direction, the first contact being in contact with the first N-type semiconductor region and the second N-type semiconductor region and being isolated from the first P-type semiconductor region; and
a second contact provided to extend along the third direction, the second contact being in contact with the first P-type semiconductor region and being isolated from the first N-type semiconductor region and the second N-type semiconductor region.

20. The device of claim 9, wherein:
the first N-type semiconductor region and the second N-type semiconductor region each contain one of phosphorus and arsenic; and
the first P-type semiconductor region contains boron.
